(19) United States
(12) Patent Application Publication
(10) Pub. No.: US 2024/0405108 A1
(43) Pub. Date: Dec. 5, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Kenji HARADA, Tokyo (JP)

(73) Assignee: Mitsubishi Electric Corporation, Tokyo (JP)

(21) Appl. No.: 18/603,935

(22) Filed: Mar. 13, 2024

(30) Foreign Application Priority Data
May 31, 2023 (JP) 2023-089358

(51) Int. Cl. H01L 29/739; H01L 27/06; H01L 29/06; H01L 29/66; H01L 29/861

(52) U.S. Cl. CPC H01L 29/7397; H01L 27/0664; H01L 29/0696; H01L 29/66136; H01L 29/66348; H01L 29/8611

(57) ABSTRACT

A semiconductor device is provided that maintains assembly and improves stress tolerance. The semiconductor device includes a plurality of trenches, a plurality of trench electrodes, an insulation film, and a first electrode. The trench electrodes are provided respectively inside the trenches. The insulation film covers two or more of the trench electrodes. The first electrode is provided on the insulation film. The insulation film has an opening provided between the two or more trench electrodes covered with the insulation film. The first electrode is provided on the semiconductor substrate to fill the opening. Each of the trench electrodes has an upper surface that includes a first recessed portion. The insulation film has an upper surface that includes a second recessed portion located immediately above the first recessed portion. The first electrode has an upper surface that includes a third recessed portion located immediately above the opening.

### BACKGROUND OF THE INVENTION

### Field of the Invention

The present disclosure relates to a semiconductor device and a method of manufacturing a semiconductor device.

### Description of the Background Art

Semiconductor devices have a structure in which semiconductor elements such as insulated gate bipolar transistors (IGBT) and diodes are provided on a semiconductor substrate. The semiconductor device disclosed in Japanese Patent Application Laid-Open No. 2019-29581 includes a contact plug that connects a semiconductor substrate and a wiring layer. The contact plug flattens electrodes to be formed thereabove and therefore improves assembly in subsequent steps of manufacturing the semiconductor device.

In the case where wiring or electrodes provided on a semiconductor substrate are flattened, the interface of each layer formed on the upper surface of the semiconductor substrate is also flattened as well. Such a layer structure is weak against lateral stress.

### SUMMARY

It is an object of the present disclosure to provide a semiconductor device that maintains assembly and improves stress tolerance.

A semiconductor device according to the present disclosure includes a plurality of trenches, a plurality of trench electrodes, an insulation film, and a first electrode. The plurality of trenches are provided on an upper surface of a semiconductor substrate. The plurality of trench electrodes are provided respectively inside the plurality of trenches. The insulation film covers two or more trench electrodes among the plurality of trench electrodes. The first electrode is provided on the insulation film. The insulation film has an opening provided between the two or more trench electrodes covered with the insulation film. The first electrode is provided on the semiconductor substrate to fill the opening. Each of the plurality of trench electrodes has an upper surface that includes a first recessed portion. The insulation film has an upper surface that includes a second recessed portion located immediately above the first recessed portion, The first electrode has an upper surface that includes a third recessed portion located immediately above the opening.

The present disclosure provides a semiconductor device that maintains assembly and improves stress tolerance.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a configuration of a semiconductor device according to an embodiment.

FIG. 2 is a plan view showing a configuration of a semiconductor device according to another embodiment.

FIG. 3 is a partial enlarged plan view showing a configuration of an IGBT area of a semiconductor device.

FIG. 4 is a sectional view showing the configuration of the IGBT area of the semiconductor device.

FIG. 5 is a partial enlarged sectional view showing the configuration of the IGBT area.

FIG. 6 is a partial enlarged sectional view showing the configuration of the IGBT area.

FIG. 7 is a partial enlarged sectional view showing the configuration of the IGBT area.

FIG. 8 is a sectional view showing the configuration of the IGBT area of the semiconductor device.

FIG. 9 is a partial enlarged plan view showing a configuration of a diode area of the semiconductor device.

FIG. 10 is a sectional view showing the configuration of the diode area of the semiconductor device.

FIG. 11 is a sectional view showing the configuration of the diode area of the semiconductor device.

FIG. 12 is a sectional view showing a configuration of a boundary portion between the IGBT area and the diode area.

FIG. 13 is a sectional view showing a configuration of a boundary portion between the IGBT area and a termination area.

FIG. 14 is a sectional view showing a configuration of a boundary portion between the diode area and the termination area.

FIG. 15 is a diagram showing a method of manufacturing the semiconductor device.

FIG. 16 is a diagram showing the method of manufacturing the semiconductor device.

FIG. 17 is a diagram showing the method of manufacturing the semiconductor device.

FIG. 18 is a diagram showing the method of manufacturing the semiconductor device.

FIG. 19 is a diagram showing the method of manufacturing the semiconductor device.

FIG. 20 is a diagram showing the method of manufacturing the semiconductor device.

FIG. 21 is a diagram showing the method of manufacturing the semiconductor device.

FIG. 22 is a diagram showing the method of manufacturing the semiconductor device.

FIG. 23 is a diagram showing the method of manufacturing the semiconductor device.

FIG. 24 is a diagram showing the method of manufacturing the semiconductor device.

FIG. 25 is a diagram showing the method of manufacturing the semiconductor device.

FIG. 26 is a diagram showing the method of manufacturing the semiconductor device.

### DESCRIPTION OF THE PREFERRED EMBODIMENTS

In the following description, n and p represent semiconductor conductivity types. Specifically, n⁻ indicates an impurity concentration of lower than n, and n⁺ indicates an impurity concentration of higher than n. Similarly, p indicates an impurity concentration of lower than p, and p+indicates an impurity concentration of higher than p. The p-type and n-type of each layer described below are interchangeable.

### (1) Overall Planar Structure of Semiconductor Device

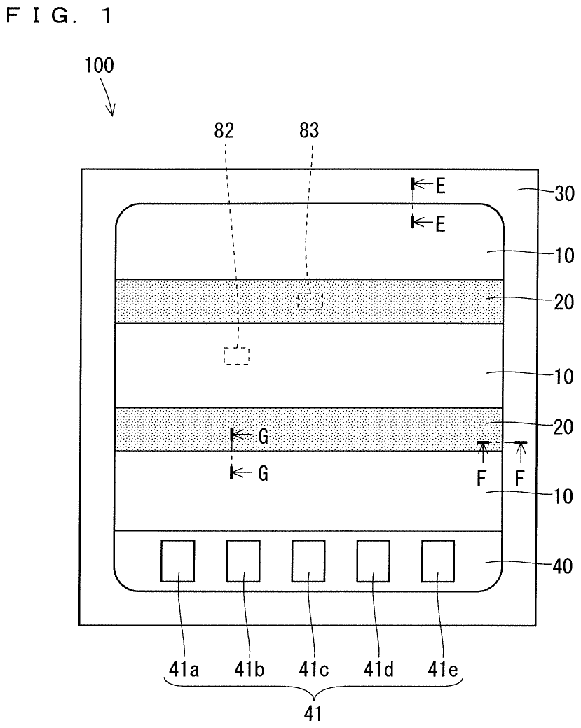

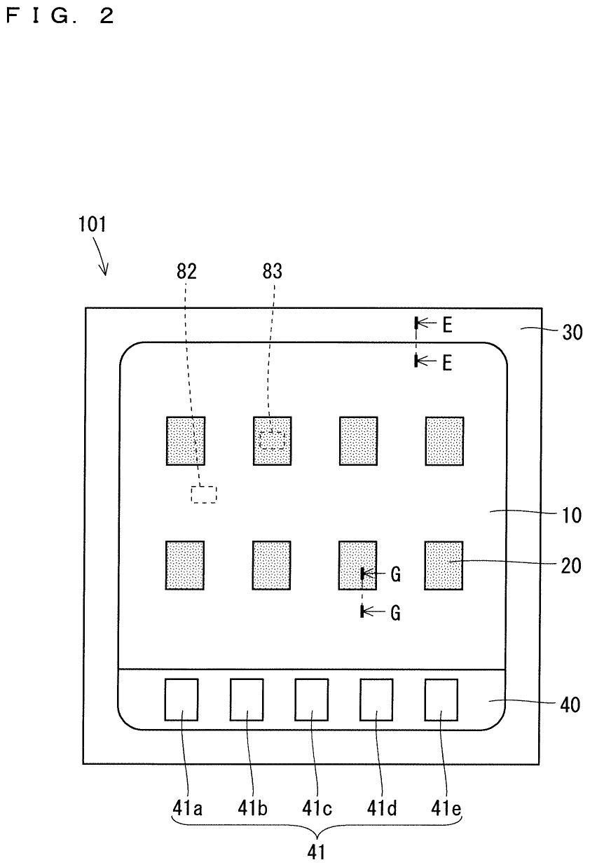

FIG. 1 is a plan view showing a configuration of a semiconductor device 100 according to an embodiment. FIG. 2 is a plan view showing a configuration of a semiconductor device 101 according to an embodiment. The semiconductor devices 100 and 101 are reverse conducting insulated bipolar transistors (RC-IGBTs) in which IGBT areas 10 and diode areas 20 are provided in one semiconductor substrate. For example, the semiconductor substrate may be formed of a semiconductor such as Si. It is preferable that the semiconductor may be formed of a so-called wide-bandgap semiconductor such as SiC, GaN, or a gallium oxide.

As shown in FIG. 1, the IGBT areas 10 and the diode areas 20 in the semiconductor device 100 extend in a direction from one end of the semiconductor device 100 to the other end. The IGBT areas 10 and the diode areas 20 are alternatively provided in a direction orthogonal to the direction of extension. The semiconductor device 100 has a striped structure in which the IGBT areas 10 and the diode areas 20 are provided in strips.

The semiconductor device 100 includes three IGBT areas 10 and two diode areas 20. The number of IGBT areas 10 and the number of diode areas 20 are, however, not limited thereto. The number of IGBT areas 10 may be three or more or less than three. The number of diode areas 20 may be two or more or less than two.

Each diode area 20 of the semiconductor device 100 is sandwiched between two IGBT areas 10. The arrangement of the IGBT areas 10 and the diode areas 20 is, however, not limited thereto. The arrangement of the IGBT areas 10 and the diode areas 20 may also be such that they change places with each other. That is, each IGBT area 10 may be sandwiched between two diode areas 20. Any configuration is possible as long as the IGBT areas 10 and the diode areas 20 are alternately arranged adjacent to each other.

As shown in FIG. 2, the semiconductor device 101 includes a plurality of diode areas 20 arranged discretely in both longitudinal and lateral directions. That is, the diode areas 20 are arranged in a matrix. The IGBT area 10 is provided around these diode areas 20. The semiconductor device 101 has such an island structure.

In the semiconductor device 101, four diode areas 20 are arranged laterally in each row, and two diode areas 20 are arranged longitudinally in each column. The number and arrangement of diode areas 20 are, however, not limited thereto. Any configuration is possible as long as one or a plurality of diode areas 20 are scattered in the IGBT area 10. In other words, any configuration is possible as long as each diode area 20 is surrounded by the IGBT area 10.

Each IGBT area 10 of the semiconductor device 100 or 101 includes a plurality of IGBT cells (not shown) formed therein. Each of the IGBT cells includes an IGBT as a semiconductor element. Each diode area 20 includes a plurality of diode cells (not shown) formed therein. Each of the diode cells includes a freewheeling diode as a semiconductor element. The structure of one cell corresponds to the smallest unit of elements. An area that includes the IGBT areas 10 and the diode areas 20 is referred to as a cell area.

As shown in FIGS. 1 and 2, the semiconductor devices 100 and 101 further include a pad area 40 and a termination area 30 in addition to the IGBT areas 10 and the diode areas 20.

The pad area 40 is provided outside the cell area, i.e., outside the IGBT areas 10 and the diode areas 20. In the present examples, the pad area 40 is provided adjacent to at least part of one IGBT area 10. The pad area 40 is an area for arranging control pads 41 in order to control the semiconductor device 100 or 101. For example, the control pads 41 may include a current sensing pad 41a, a Kelvin emitter pad 41b, a gate pad 41c, and temperature sensing diode pads 41d and 41e.

The current sensing pad 41a is a control pad for sensing current flowing through the cell area. The current sensing pad 41a is electrically connected to some of the IGBT cells or the diode cells in the cell area so as to allow passage of a fraction of an integral multiple or several tens of thousands of current flowing through the entire cell area.

The Kelvin emitter pad 41b and the gate pad 41c are control pads to which a gate driving voltage for controlling on and off of the semiconductor device 100 or 101 is applied. The Kelvin emitter pad 41b is electrically connected to p-type base layers and n⁺-type source layers (both of which are not shown) of the IGBT cells. The Kelvin emitter pad 41b and the p-type base layers may be electrically connected via p⁺-type contact layers (not shown) to each other. The gate pad 41c is electrically connected to gate trench electrodes (not shown) of the IGBT cells.

The temperature sensing diode pads 41d and 41e are control pads electrically connected to anodes and cathodes of temperature sensing diodes (not shown) provided in the cell area. The temperature sensing diode pads 41d and 41e measure voltages between the anodes and cathodes of the temperature sensing diodes to measure the temperature of the semiconductor device 100 or 101.

The termination area 30 is provided around an area that combines the cell area and the pad area 40. The termination area 30 has a structure for holding withstand voltage of the semiconductor device 100 or 101. Various structures may be selected as appropriate as a withstand voltage holding structure. Examples of the withstand-voltage holding structure include variation of lateral doping (VLD) and field limiting ring (FLR) formed in the surface layer of a first main surface side (upper surface side) of the semiconductor substrate. The FLR includes p-type terminal well layers (not shown) that surround the cell area. The VLD includes a p-type well layer (not shown) that surround the cell area and has a concentration gradient. The number of ring-shaped p-type terminal well layers, which configure the FLR, and the concentration distribution of the p-type well layer, which configures the VLD, are selected as appropriate depending on the withstand voltage design of the semiconductor device 100 or 101. The pad area 40 may further include a p-type terminal well layer arranged across almost the entire area. The pad area 40 may further include IGBT cells or diode cells.

### (2) Structure of IGBT Area 10

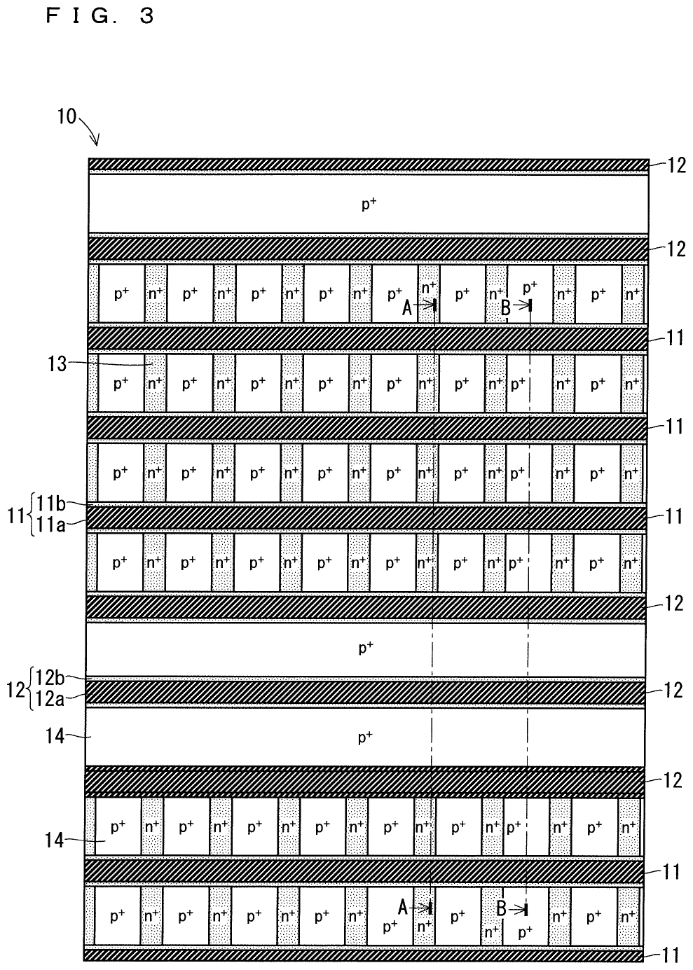

FIG. 3 is a partial enlarged plan view showing a configuration of one IGBT area 10 of the semiconductor device 100 or 101. FIG. 3 shows the configuration in an area 82 shown in FIG. 1 or 2 in enlarged dimensions.

The IGBT area 10 of the semiconductor devices 100 and 101 includes active trenches 11 and dummy trenches 12 arranged therein.

In the semiconductor device 100, the active trenches 11 and the dummy trenches 12 extend in the longitudinal direction of the IGBT area 10. The active trenches 11 and the dummy trenches 12 are long in the direction of extension of the IGBT area 10. The longitudinal direction of the IGBT area 10 corresponds to the right-left direction in FIG. 3.

In the semiconductor device 101, the active trenches 11 and the dummy trenches 12 extend in one direction. For example, the active trenches 11 and the dummy trenches 12 may extend in either the up-down direction or the right-left direction in FIG. 2.

Each active trench 11 includes a gate trench electrode 11a and a gate-trench insulation film 11b. Although details of a sectional structure of the active trench 11 will be described later, the gate-trench insulation film 11b is formed along the inner wall of a trench structure formed in the depth direction from the first main surface, i.e., the upper surface, of the semiconductor substrate. The gate trench electrode 11a is formed inside the trench structure via the gate-trench insulation film 11b. The gate trench electrode 11a is electrically connected to the gate pad 41c (not shown).

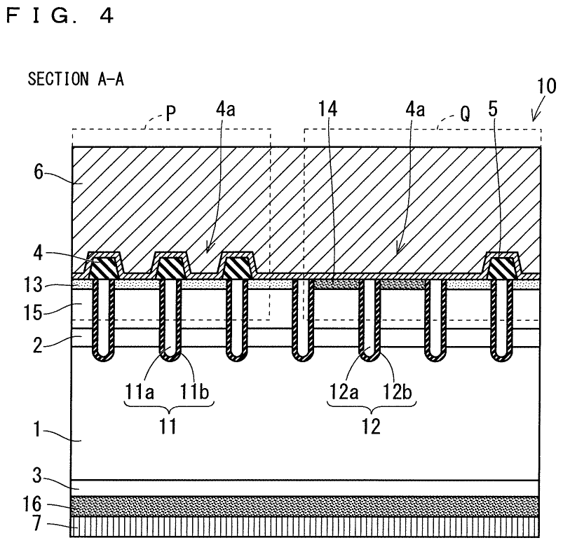

Each dummy trench 12 includes a dummy trench electrode 12a and a dummy-trench insulation film 12b. Although details of a sectional structure of the dummy trench 12 will be described later, the dummy-trench insulation film 12b is formed along the inner wall of a trench structure formed in the depth direction from the first main surface of the semiconductor substrate. The dummy trench electrode 12a is formed inside the trench structure via the dummy-trench insulation film 12b. The dummy trench electrode 12a is electrically connected to an emitter electrode 6 (see FIG. 4) that is provided above the first main surface of the semiconductor device 100 or 101.

In areas of the IGBT area 10 where the active trenches 11 are provided, an n⁺-type source layer 13 and a p+-type contact layer 14 are selectively provided as surface layers on the first main surface side of the semiconductor substrate. The n⁺-type source layer 13 and the p⁺-type contact layer 14 are alternately provided in the direction of extension of the active trenches 11. The active trenches 11 are provided so as to cross over the n⁺-type source layer 13 and the p⁺-type contact layer 14. Part of the gate-trench insulation film 11b of each active trench 11 is in contact with the n⁺-type source layer 13.

In areas of the IGBT area 10 where the dummy trenches 12 are provided, the p⁺-type contact layer 14 is provided as a surface layer on the first main surface of the semiconductor substrate. The p⁺-type contact layer 14 is provided between two adjacent dummy trenches 12.

In FIG. 3, three dummy trenches 12 are arranged adjacent to three active trenches 11. Furthermore, other three active trenches 11 are arranged adjacent to the three dummy trenches 12. That is, one active trench group that includes three active trenches 11 and one dummy trench group that includes three dummy trenches 12 are arranged alternately. The number of active trenches 111 included in one active trench group is not limited to three, and may be one or more. The number of dummy trenches 12 included in one dummy trench group is not limited to three, and may be one or more. It is, however, noted that the dummy trenches 12 are not necessarily required in the semiconductor device 100 or 101. That is, all the trenches provided in the IGBT area 10 may be active trenches 11.

FIG. 4 is a sectional view showing the configuration of one IGBT area 10 of the semiconductor device 100 or 101. FIG. 4 shows a section taken along a broken line A-A in FIG. 3.

In the IGBT area 10, the semiconductor device 100 or 101 includes an n⁺-type source layer 13, a p⁺-type contact layer 14, a p-type base layer 15, an n-type carrier stored layer 2, an n⁻-type drift layer 1, an n-type buffer layer 3, a p-type collector layer 16, active trenches 11, dummy trenches 12, an interlayer insulation film 4, a barrier metal 5, an emitter electrode 6, and a collector electrode 7.

For example, one IGBT cell may correspond to an area sectioned for each active trench 11. The IGBT cell includes the n⁺-type source layer 13, the p-type base layer 15, the n-type carrier stored layer 2, the n⁻-type drift layer 1, the n-type buffer layer 3, the p-type collector layer 16, the active trench 11, the interlayer insulation film 4, the barrier metal 5, the emitter electrode 6, and the collector electrode 7.

The first main surface of the semiconductor substrate in the IGBT area 10 corresponds to the surfaces (upper surfaces) of the n⁺-type source layer 13 and the p⁺-type contact layer 14. The first main surface is the upper surface of the semiconductor substrate. The second main surface of the semiconductor substrate in the IGBT area 10 corresponds to the surface (lower surface) of the p-type collector layer 16. The second main surface is the surface on side opposite to the first main surface and is the lower surface of the semiconductor substrate. In FIG. 4, the semiconductor substrate corresponds to the range from the upper surfaces of the n⁺-type source layer 13 and the p⁺-type contact layer 14 to the lower surface of the p-type collector layer 16.

The n-type drift layer 1 is formed of the semiconductor substrate. The n⁻-type drift layer 1 is provided between the first and second main surfaces of the semiconductor substrate. The n⁻-type drift layer 1 is a semiconductor layer that may contain, for example, arsenic (As) or phosphorus (P) as an n-type impurity. The concentration of the n-type impurity in the n⁻-type drift layer 1 may preferably be higher than or equal to 1.0E+12/cm³ and lower than or equal to 1.0E+15/cm³.

The n-type carrier stored layer 2 is provided on the first main surface side of the semiconductor substrate with respect to the n⁻-type drift layer 1. The n-type carrier stored layer 2 is a semiconductor layer that may contain, for example, arsenic or phosphorus as an n-type impurity. The n-type carrier stored layer 2 has a higher n-type impurity concentration than the n⁻-type drift layer 1. The concentration of the n-type impurity in the n-type carrier stored layer 2 may preferably be higher than or equal to 1.0E+13/cm³ and lower than or equal to 1.0E+17/cm³. The n-type carrier stored layer 2 reduces current-carrying losses during the current flow through the IGBT area 10. The n-type carrier stored layer 2 and the n⁻-type drift layer 1 may be combined and defined as one n-type drift layer. The n-type carrier stored layer 2 is not necessarily required, and the n-type drift layer 1 may be provided in the position of the n-type carrier stored layer 2.

The p-type base layer 15 is provided on the first main surface side of the semiconductor substrate with respect to the n-type carrier stored layer 2. The p-type base layer 15 is a semiconductor layer that may contain, for example, boron (B) or aluminum (Al) as a p-type impurity. The concentration of the p-type impurity in the p-type base layer 15 may preferably be higher than or equal to 1.0E+12/cm³ and lower than or equal to 1.0E+19/cm³. The p-type base layer 15 is in contact with the gate-trench insulation films 11b of the active trenches 11. When a gate driving voltage is applied to the gate trench electrodes 11a, a channel is formed in the p-type base layer 15.

The n⁺-type source layer 13 is provided on the first main surface side of the semiconductor substrate with respect to the p-type base layer 15. The n⁺-type source layer 13 is selectively provided in the upper part of the p-type base layer 15 as a surface layer of the semiconductor substrate. The n⁺-type source layer 13 is a semiconductor layer that may contain, for example, arsenic or phosphorus as an n-type impurity. The concentration of the n-type impurity in the n⁺-type source layer 13 may preferably be higher than or equal to 1.0E+17/cm³ and lower than or equal to 1.0E+20/cm³. The n⁺-type source layer 13 may also be referred to as an n⁺-type emitter layer.

The p⁺-type contact layer 14 is provided on the first main surface side of the semiconductor substrate with respect to the p-type base layer 15. The p⁺-type contact layer 14 is selectively provided in the upper part of the p-type base layer 15 as a surface layer of the semiconductor substrate The p⁺-type contact layer 14 is provide in an area of the upper part of the p-type base layer 15 in which the n⁺-type source layer 13 is not provided. The p⁺-type contact layer 14 is a semiconductor layer that may contain, for example, boron or aluminum as a p-type impurity. The p⁺-type contact layer 14 has a higher p-type impurity concentration than the p-type base layer 15. The concentration of the p-type impurity in the p⁺-type contact layer 14 may preferably be higher than or equal to 1.0E+15/cm³ and lower than or equal to 1.0E+20/cm³. The p⁺-type contact layer 14 and the p-type base layer 15 may be collectively defined as one p-type base layer.

The n-type buffer layer 3 is provided on the second main surface side of the semiconductor substrate with respect to the n⁻-type drift layer 1. The n-type buffer layer 3 is a semiconductor layer that may contain, for example, at least either phosphorus or proton (H⁺) as an n-type impurity. The n-type buffer layer 3 has a higher n-type impurity concentration than the n⁻-type drift layer 1. The concentration of the n-type impurity in the n-type buffer layer 3 may preferably be higher than or equal to 1.0E+12/cm³ and lower than or equal to 1.0E+18/cm³. The n-type buffer layer 3 reduces the occurrence of punch-through resulting from extension of a depletion layer from the p-type base layer 15 toward the second main surface when the semiconductor device 100 is in the OFF state. The n-type buffer layer 3 and the n⁻-type drift layer 1 may be collectively defined as one n-type drift layer. Moreover, the n-type carrier stored layer 2, the n-type buffer layer 3, and the n⁻-type drift layer 1 may be collectively defined as one n-type drift layer. The n-type buffer layer 3 is not necessarily required, and the n⁻-type drift layer 1 may be provided in the position of the n-type buffer layer 3.

The p-type collector layer 16 is provided on the second main surface side of the semiconductor substrate with respect to the n-type buffer layer 3. The p-type collector layer 16 is a semiconductor layer that may contain, for example, boron or aluminum as a p-type impurity. The concentration of the p-type impurity in the p-type collector layer 16 may preferably be higher than or equal to 1.0E+16/cm³ and lower than or equal to 1.0E+20/cm³.

The active trenches 11 are provided in the first main surface, i.e., the upper surface, of the semiconductor substrate. The active trenches 11 extend from the first main surface to the n-type drift layer 1 through the n⁺-type source layer 13, the p-type base layer 15, and the n-type carrier stored layer 2.

The gate-trench insulation films 11b are formed along the inner walls of the trench structures that are formed in the depth direction from the first main surface of the semiconductor substrate. The gate-trench insulation films 11b are in contact with the n⁺-type source layer 13 and the p-type base layer 15. For example, the gate-trench insulation films 11b may be oxide films.

The gate trench electrodes 11a are formed inside the trench structures via the gate-trench insulation films 11b. The bottoms of the gate trench electrodes 11a face the n⁻-type drift layer 1 via the gate-trench insulation films 11b. For example, the gate trench electrode 11a may be formed of conductive polysilicon. When a gate driving voltage is applied to the gate trench electrodes 11a, a channel is formed in the p-type base layer 15 that is in contact with the gate-trench insulation films 11b.

The dummy trenches 12 are provided in the first main surface, i.e., the upper surface, of the semiconductor substrate. The dummy trenches 12 extend from the first main surface of the semiconductor substrate to the n⁻-type drift layer 1 through the p⁺-type contact layer 14, the p-type base layer 15, and the n-type carrier stored layer 2.

The dummy-trench insulation films 12b are formed along the inner walls of the trench structures that are formed in the depth direction from the first main surface of the semiconductor substrate. For example, the dummy-trench insulation films 12b may be oxide films.

The dummy trench electrodes 12a are formed inside the trench structures via the dummy-trench insulation films 12b. The bottoms of the dummy trench electrodes 12a face the n⁻-type drift layer 1 via the dummy-trench insulation films 12b. For example, the dummy trench electrodes 12a may be formed of conductive polysilicon.

The interlayer insulation film 4 is provided on the gate trench electrodes 11a of the active trenches 11.

The barrier metal 5 is formed on the interlayer insulation film 4 and on areas of the first main surface of the semiconductor substrate on which the interlayer insulation film 4 is not provided. For example, the barrier metal 5 may be formed of titanium-containing metal such as Ti, TiN, or TiSi. Examples of the titanium-containing metal include titanium nitride and TiSi. TiSi is an alloy of titanium and silicon (Si). The barrier metal 5 is in ohmic contact with the n⁺-type source layer 13, the p⁺-type contact layer 14, and the dummy trench electrodes 12a. The barrier metal 5 is electrically connected to the n⁺-type source layer 13, the p⁺-type contact layer 14, and the dummy trench electrodes 12a.

The emitter electrode 6 is provided on the barrier metal 5. For example, the emitter electrode 6 may be formed of an aluminum-silicon alloy (Al—Si-based alloy). The emitter electrode 6 is electrically connected to the n⁺-type source layer 13, the p⁺-type contact layer 14, and the dummy trench electrodes 12a via the barrier metal 5. The emitter electrode 6 may be configured of a plurality of metal films including an aluminum alloy film and other metal films. For example, the emitter electrode 6 may be configured of an aluminum alloy film and a plated film. The plated film may be formed by, for example, electroless plating or electroplating. For example, the plated film may be a nickel (Ni) film. In fine areas of the interlayer insulation film 4 that are adjacent to each other, a tungsten film may be formed, and the emitter electrode 6 may be formed on the tungsten film. In this case, the emitter electrode 6 are formed with excellent properties because the tungsten film has greater embeddedness than the plating film.

The barrier metal 5 and the emitter electrode 6 may be collectively defined as one emitter electrode. The barrier metal 5 is not necessarily required. In the case where the barrier metal 5 is not provided, the emitter electrode 6 may be provided on the n⁺-type source layer 13, the p⁺-type contact layer 14, and the dummy trench electrodes 12a in ohmic contact with them. Alternatively, the barrier metal 5 may be provided only on the n-type semiconductor layers such as the n⁺-type source layer 13, and the interlayer insulation film 4 may be provided on part of the dummy trench electrodes 12a. In that case, the emitter electrode 6 is electrically connected to the dummy trench electrodes 12a on any areas of the dummy trench electrodes 12a.

The collector electrode 7 is provided on the p-type collector layer 16. Like the emitter electrode 6, the collector electrode 7 may be formed of, for example, an aluminum alloy. The collector electrode 7 is in ohmic contact with the p-type collector layer 16 and electrically connected to the p-type collector layer 16. The collector electrode 7 may be configured of an aluminum alloy and a plating film. The collector electrode 7 may also have a different configuration from that of the emitter electrode 6.

As shown in FIG. 4, the semiconductor devices 100 and 101 include a plurality of active trenches 11 and a plurality of dummy trenches 12 as a plurality of trenches. Inside the active trenches 11, the gate trench electrodes 11a are provided as first trench electrodes. Inside the dummy trenches 12, the dummy trench electrodes 12a are provided as second trench electrodes. The gate trench electrodes 11a and the dummy trench electrodes 12a are collectively referred to as a plurality of trench electrodes. The interlayer insulation film 4 covers two or more first trench electrodes, i.e., two or more gate trench electrodes 11a, among the plurality of trench electrodes.

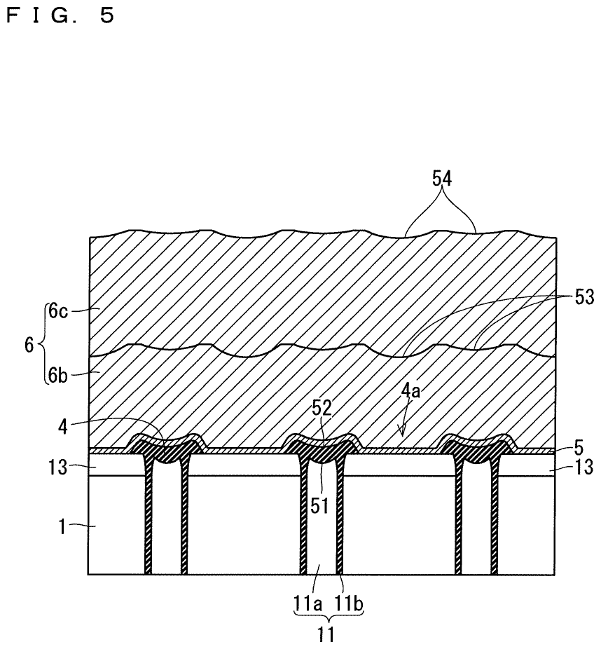

FIG. 5 is a partial enlarged sectional view showing the configuration of one IGBT area 10. FIG. 5 shows the configuration of an area P in FIG. 4.

The upper surface of each gate trench electrode 11a includes a first recessed portion 51. The first recessed portion 51 is provided in the central portion of the upper end in the widthwise direction of the gate trench electrode 11a. The widthwise direction refers to the direction orthogonal to the direction of extension of the gate trench electrodes 11a. The first recessed portion 51 has a bottom located at a lower level than the upper surface of the semiconductor substrate. The gate trench electrode 11a has an upper end located at a lower level than the upper surface of the semiconductor substrate.

The interlayer insulation film 4 has an upper surface that includes second recessed portions 52 located immediately above the first recessed portions 51. The second recessed portions 52 are formed to follow the shapes of the first recessed portions 51. The second recessed portions 52 are located in the central portion of the upper surface of the interlayer insulation film 4.

The interlayer insulation film 4 includes openings 4a. The openings 4a are provided between the plurality of gate trench electrodes 11a covered with the interlayer insulation film 4. It is preferable that the openings 4a may have a bottom having a greater width than the height of the interlayer insulation film 4 that forms side walls of the openings 4a.

For example, the interlayer insulation film 4 may have a single-layer structure including an oxide film. For example, the oxide film in the single-layer structure may be formed of tetraethoxysilane (TEOS). The interlayer insulation film 4 may have a laminated structure including a plurality of oxide films. In the case where the interlayer insulation film 4 has a laminated structure, a plurality of oxide films in the laminated structure may be two or more types of oxide films having different dopant concentrations. Among the two or more types of oxide films, one oxide film may be formed of TEOS that contains boron and phosphorus (BPTEOS), and the other oxide films may be formed of TEOS.

The emitter electrode 6 includes a first emitter electrode 6b and a second emitter electrode 6c. The first emitter electrode 6b is provided on the semiconductor substrate so as to fill the openings 4a of the interlayer insulation film 4 via the barrier metal 5. In other words, the barrier metal 5 and the emitter electrode 6 are formed in the spaces of the openings 4a. It is, however, noted that the barrier metal 5 is not necessarily required. In the case where the barrier metal 5 is not provided, the first emitter electrode 6b is in contact with the upper surface of the semiconductor substrate at the bottoms of the openings 4a.

The first emitter electrode 6b has an upper surface that includes third recessed portions 53 located immediately above the second recessed portions 52 and the openings 4a. The third recessed portions 53 are formed so as to follow the shapes of the second recessed portions 52 or the openings 4a. Although the third recessed portions 53 shown in FIG. 5 are located immediately above both of the second recessed portions 52 and the openings 4a, the third recessed portions 53 located immediately above the second recessed portions 52 are not necessarily required.

The second emitter electrode 6c is provided on the first emitter electrode 6b. For example, the second emitter electrode 6c may have a laminated structure that includes two or more types of metal layers. For example, the laminated structure may include an Ni film, a Pd film, and an Au film in order from the first main surface side of the semiconductor substrate.

The second emitter electrode 6c may have an upper surface that includes fourth recessed portions 54 located immediately above the third recessed portions 53. The fourth recessed portions 54 are formed so as to follow the shapes of the third recessed portions 53. Preferably, the fourth recessed portions 54 may have depths shallower than the depth of the third recessed portions 53. The depths of the fourth recessed portions 54 may also preferably be shallower than the depths of the second recessed portions 52 and the openings 4a. The depths of the fourth recessed portions 54 may preferably be shallower than the depths of the first recessed portions 51.

The first emitter electrode 6b may have a greater thickness than the second emitter electrode 6c, or conversely the second emitter electrode 6c may have a greater thickness than the first emitter electrode 6b. In the case where the thickness of the first emitter electrode 6b is greater than the thickness of the second emitter electrode 6c, stress tolerance improves. In the case where the thickness of the second emitter electrode 6c is greater than the thickness of the first emitter electrode 6b, the second emitter electrode 6c exhibits improved surface wettability and achieves high assembly.

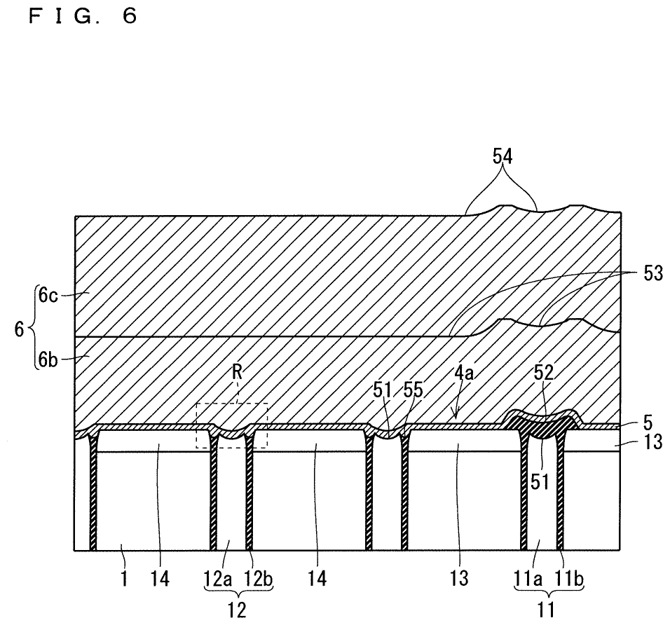

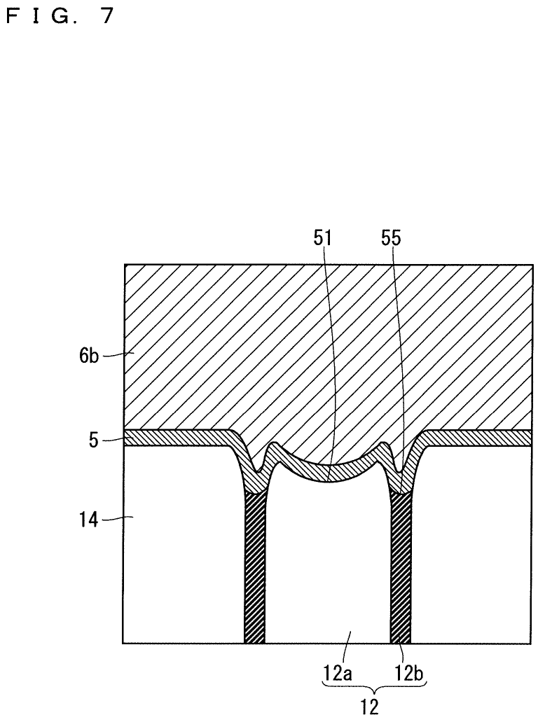

FIGS. 6 and 7 are partial enlarged sectional views showing the configuration of the IGBT area 10. FIG. 6 shows the configuration of an area Q shown in FIG. 4. FIG. 7 shows the configuration of an area R shown in FIG. 6.

As shown in FIGS. 3 and 4, the dummy trench electrodes 12a are provided between two gate trench electrodes 11a covered with the interlayer insulation film 4. In other words, three dummy trench electrodes 12a are provided inside one opening 4a of the interlayer insulation film 4. The dummy trench electrodes 12a are not covered with the interlayer insulation film 4 and are electrically connected to the emitter electrode 6. Although the three dummy trench electrodes 12a are shown in FIGS. 4 and 6, the number of dummy trench electrodes 12a provided inside one opening 4a may be one or more.

As shown in FIGS. 6 and 7, the upper surface of each dummy trench electrode 12a includes a first recessed portion 51. The first recessed portion 51 is provided in the central portion of the upper end in the widthwise direction of the dummy trench electrode 12a. The first recessed portion 51 has a bottom located at a lower level than the upper surface of the semiconductor substrate. The dummy trench electrode 12a has an upper end located at a lower level than the upper surface of the semiconductor substrate. The first recessed portion 51 forms the bottom of the opening 4a.

The upper surface of each dummy-trench insulation film 12b that is in contact with the dummy trench electrode 12a includes fifth recessed portions 55. The fifth recessed portions 55 are located at a lower level than the upper surface of the semiconductor substrate. The fifth recessed portions 55 form the bottom of the opening 4a.

The first emitter electrode 6b is provided on the semiconductor substrate so as to fill the openings 4a of the interlayer insulation film 4 via the barrier metal 5. Although the barrier metal 5 is formed on the first recessed portions 51 and the fifth recessed portions 55, the first emitter electrode 6b may be formed on the first recessed portions 51 and the fifth recessed portions 55 if the barrier metal 5 is not provided.

As shown in FIG. 6, the first emitter electrode 6b has an upper surface that includes third recessed portions 53 located immediately above the openings 4a. The third recessed portions 53 may further include recessed portions (not shown in FIG. 6) immediately above the first recessed portions 51 provided on the inner sides of the openings 4a. The third recessed portions 53 are formed so as to follow the shapes of the first recessed portions 51 or the openings 4a.

The second emitter electrode 6c is provided on the first emitter electrode 6b. The second emitter electrode 6c may have an upper surface that includes fourth recessed portions 54 immediately above the third recessed portions 53. The fourth recessed portions 54 are formed so as to follow the shapes of the third recessed portions 53.

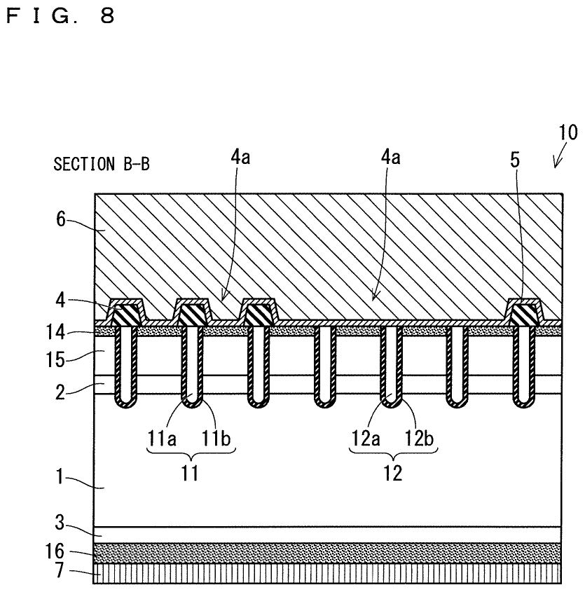

FIG. 8 is a sectional view showing the configuration of one IGBT area 10 of the semiconductor device 100 or 101. FIG. 8 shows a section taken along a broken line B-B shown in FIG. 3.

The section shown in FIG. 8 differs from the section shown in FIG. 4 in that the n⁺-type source layer 13 is not provided as a surface layer on the first main surface side of the semiconductor substrate. As shown in FIG. 3, the n⁺-type source layer 13 is selectively provided as a surface layer on the first main surface side of the semiconductor substrate. Thus, the n⁺-type source layer 13 does not exist in the section shown in FIG. 8.

Although not shown, the semiconductor devices 100 and 101 with the configuration shown in FIG. 8 further include the first to fifth recessed portions 51 to 55 and the openings 4a as in the configuration shown in FIGS. 5 to 7.

### (3) Structure of Diode Area 20

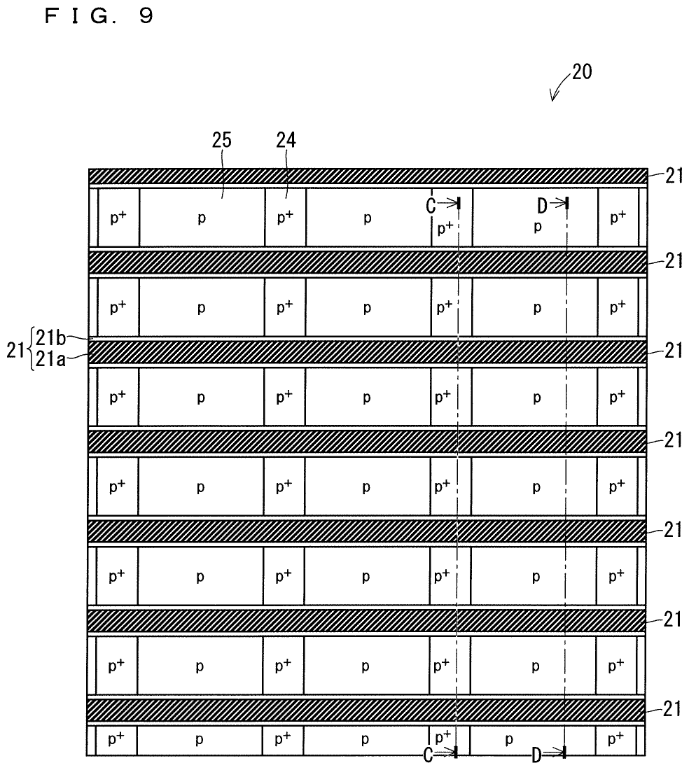

FIG. 9 is a partial enlarged plan view showing a configuration of one diode area 20 of the semiconductor device 100 or 101. FIG. 9 shows the configuration of an area 83 shown in FIGS. 1 and 2 in enlarged dimensions.

The semiconductor devices 100 and 101 include the diode trenches 21 provided in the diode area 20.

The diode trenches 21 extend in one direction. The diode trenches 21 according to the embodiment extend in the same direction as the active trenches 11 and the dummy trenches 12.

Each diode trench 21 includes a diode trench insulation film 21b and a diode trench electrode 21a. Although details of the sectional structure of the diode trench 21 will be describe later, the diode trench insulation film 21b is formed along the inner wall of a trench structure formed in the depth direction from the first main surface of the semiconductor substrate. The diode trench electrode 21a is formed inside the trench structure via the diode trench insulation film 21b.

In the diode area 20, a p⁺-type contact layer 24 and a p-type anode layer 25 are selectively provided as surface layers on the first main surface side of the semiconductor substrate. In the present embodiment, the p⁺-type contact layer 24 and the p-type anode layer 25 are alternately provided in the direction of extension (longitudinal direction) of the diode trenches 21. The diode trenches 21 cross over the p⁺-type contact layer 24 and the p-type anode layer 25. The p⁺-type contact layer 24 and the p-type anode layer 25 are provided between two adjacent diode trenches 21.

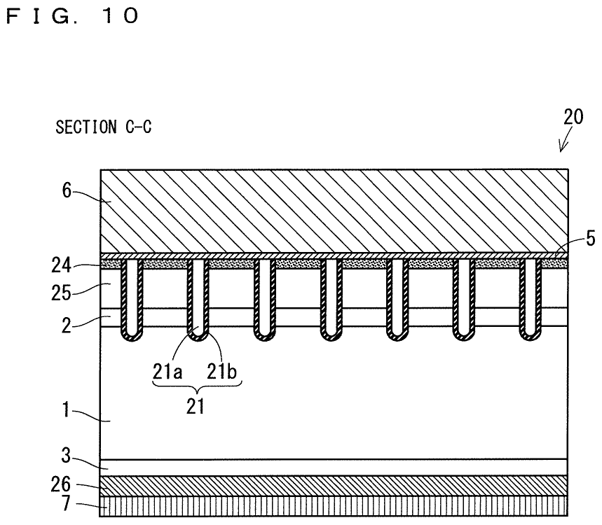

FIG. 10 is a sectional view showing the configuration of the diode area 20 of the semiconductor device 100 or 101. FIG. 10 shows a section taken along a broken line C-C shown in FIG. 9.

In the diode area 20, the semiconductor devices 100 and 101 include the p⁺-type contact layer 24, the p-type anode layer 25, the n-type carrier stored layer 2, the n⁻-type drift layer 1, the n-type buffer layer 3, an n⁺-type cathode layer 26, the diode trenches 21, the barrier metal 5, the emitter electrode 6, and the collector electrode 7.

For example, one diode cell may correspond to an area sectioned for each diode trench 21. The diode cell includes the p⁺-type contact layer 24, the p-type anode layer 25, the n-type carrier stored layer 2, the n-type drift layer 1, the n-type buffer layer 3, the n⁺-type cathode layer 26, the diode trenches 21, the barrier metal 5, the emitter electrode 6, and the collector electrode 7.

The first main surface of the semiconductor substrate in the diode area 20 corresponds to the surface (upper surface) of the p⁺-type contact layer 24. This first main surface in the diode area 20 continues from the first main surface in the IGBT area 10 and is in the same surface as the first main surface in the IGBT area 10. The second main surface of the semiconductor substrate in the diode area 20 corresponds to the surface (lower surface) of the n⁺-type cathode layer 26. This second main surface in the diode area 20 continues from the second main surface in the IGBT area 10 and is in the same surface as the second main surface in the IGBT area 10. In FIG. 10, the semiconductor substrate corresponds to the range from the upper surface of the p⁺-type contact layer 24 to the lower surface of the n⁺-type cathode layer 26.

The n-type drift layer 1 is formed of the semiconductor substrate. Like the n-type drift layer 1 in the IGBT area 10, the n⁻-type drift layer 1 in the diode area 20 is provided between the first and second main surfaces of the semiconductor substrate. The n⁻-type drift layer 1 in the diode area 20 is continuously and integrally formed with the n⁻-type drift layer 1 in the IGBT area 10. In other words, the n-type drift layer 1 in the diode area 20 and the n-type drift layer 1 in the IGBT area 10 form one semiconductor substrate.

The n-type carrier stored layer 2 is provided on the first main surface side of the semiconductor substrate with respect to the n-type drift layer 1. The n-type carrier stored layer 2 provided in the diode area 20 has the same configuration as the n-type carrier stored layer 2 provided in the IGBT area 10. For example, the n-type carrier stored layer 2 in the diode area 20 has the same thickness and the same impurity concentration as the n-type carrier stored layer 2 in the IGBT area 10.

The p-type anode layer 25 is provided on the first main surface side of the semiconductor substrate with respect to the n-type carrier stored layer 2. The p-type anode layer 25 is a semiconductor layer that may contain, for example, boron or aluminum as a p-type impurity. The concentration of the p-type impurity in the p-type anode layer 25 may preferably be higher than or equal to 1.0E+12/cm³ and lower than or equal to 1.0E+19/cm³. For example, the p-type anode layer 25 may have the same p-type impurity concentration as the p-type base layer 15 in the IGBT area 10. When having the same p-type impurity concentration, the p-type anode layer 25 and the p-type base layer 15 may be formed at the same time. Alternatively, for example, the p-type anode layer 25 may have a lower p-type impurity concentration than the p-type base layer 15 in the IGBT area 10. The lower p-type impurity concentration in the p-type anode layer 25 causes a reduction in the number of holes injected into the diode area 20 during diode operation. Accordingly, the recovery loss will decrease during diode operation.

The p⁺-type contact layer 24 is provided on the first main surface side of the semiconductor substrate with respect to the p-type anode layer 25. As shown in FIG. 9, the p⁺-type contact layer 24 is selectively formed in the upper part of the p-type anode layer 25 as a surface layer on the first main surface side of the semiconductor substrate. However, in the section C-C shown in FIG. 10, the p⁺-type contact layer 24 covers the entire surface of the p-type anode layer 25. The p⁺-type contact layer 24 is a semiconductor layer that may contain, for example, boron or aluminum as a p-type impurity. The concentration of the p-type impurity in the p⁺-type contact layer 24 may preferably be higher than or equal to 1.0E+15/cm³ and lower than or equal to 1.0E+20/cm³. The p⁺-type contact layer 24 may have the same p-type impurity concentration as the p⁺-type contact layer 14 in the IGBT area 10, or may have a different p-type impurity concentration therefrom. The p⁺-type contact layer 24 and the p-type anode layer 25 may be collectively defined as one p-type anode layer.

The n-type buffer layer 3 is provided on the second main surface side of the semiconductor substrate with respect to the n⁻-type drift layer 1. The n-type buffer layer 3 provided in the diode area 20 extends in the same plane as the n-type buffer layer 3 provided in the IGBT area 10 and has the same configuration. For example, the n-type buffer layer 3 in the diode area 20 may have the same thickness and the same impurity concentration as the n-type buffer layer 3 in the IGBT area 10. The n-type buffer layer 3 and the n⁻-type drift layer 1 may be collectively defined as one n-type drift layer. Moreover, the n-type carrier stored layer 2, the n-type buffer layer 3, and the n-type drift layer 1 may be collectively defined as one n-type drift layer. The n-type buffer layer 3 is not necessarily required, and the n-type drift layer 1 may be provided in the position of the n-type buffer layer 3.

The n⁺-type cathode layer 26 is provided on the second main surface side of the semiconductor substrate with respect to the n-type buffer layer 3. The n⁺-type cathode layer 26 is a semiconductor layer that may contain, for example, arsenic or phosphorus as an n-type impurity. The concentration of the n-type impurity in the n⁺-type cathode layer 26 may preferably be higher than or equal to 1.0E+16/cm³ and lower than or equal to 1.0E+21/cm³.

The n⁺-type cathode layer 26 may be provided in the entire diode area 20, or may be provided in part of the diode area 20. Although not shown, the semiconductor devices 100 and 101 may include a semiconductor layer in which the n⁺-type cathode layer 26 and a p⁺-type cathode layer are alternately arranged, as a semiconductor layer that configures the second main surface of the semiconductor substrate in the diode area 20. For example, such a structure may be formed by a step of selectively implanting a p-type impurity into part of an area in which the n⁺-type cathode layer 26 is formed. A diode that includes such a semiconductor layer in which the n⁺-type cathode layer 26 and the p⁺-type cathode layer are alternately arranged is called a relaxed field of cathode) (RFC) diode.

The diode trenches 21 are provided in the first main surface, i.e., the upper surface, of the semiconductor substrate. The diode trenches 21 extend from the first main surface of the semiconductor substrate to the n⁻-type drift layer 1 through the p⁺-type contact layer 24, the p-type anode layer 25, and the n-type carrier stored layer 2.

The diode trench insulation films 21b are formed along the inner walls of trench structures formed in the depth direction from the first main surface of the semiconductor substrate. For example, the diode trench insulation films 21b may be oxide films.

The diode trench electrodes 21a are formed inside the trench structures via the diode trench insulation films 21b. The bottoms of the diode trench electrodes 21a face the n⁻-type drift layer 1 via the diode trench insulation films 21b. For example, the diode trench electrodes 21a may be formed of conductive polysilicon.

The barrier metal 5 is provided on the p⁺-type contact layer 24 and on the diode trench electrodes 21a. The barrier metal 5 may have the same configuration as the barrier metal 5 in the IGBT area 10. For example, the barrier metal 5 may be formed of titanium-containing metal such as Ti, TiN, or TiSi. The barrier metal 5 is in ohmic contact with the p⁺-type contact layer 24 and the diode trench electrodes 21a.

The emitter electrode 6 is provided on the barrier metal 5. The emitter electrode 6 continues from the emitter electrode 6 in the IGBT area 10. For example, the emitter electrode 6 may preferably be formed of an aluminum alloy (Al—Si-based alloy). The emitter electrode 6 is electrically connected to the diode trench electrodes 21a and the p⁺-type contact layer 24 via the barrier metal 5.

The barrier metal 5 and the emitter electrode 6 may be collectively defined as one emitter electrode. The barrier metal 5 is not necessarily required. In the case where the barrier metal 5 is provided, the emitter electrode 6 is provided on the p-type anode layer 25, on the p⁺-type contact layer 24, and on the diode trench electrode 21a and has ohmic contact therewith. The interlayer insulation film 4 may be provided on part of the diode trench electrodes 21a. In this case, the emitter electrode 6 is electrically connected to these diode trench electrodes 21a on any areas of the diode trench electrodes 21a.

The collector electrode 7 is provided on the n⁺-type cathode layer 26. The collector electrode 7 continues from the collector electrode 7 in the IGBT area 10. The collector electrode 7 may preferably be formed of an aluminum alloy. The collector electrode 7 is in ohmic contact with the n⁺-type cathode layer 26.

Although not shown, even in the diode area 20 shown in FIG. 10, the semiconductor devices 100 and 101 include the first recessed portions 51, the third recessed portions 53, the fourth recessed portions 54, and the fifth recessed portions 55.

The semiconductor devices 100 and 101 include a plurality of active trenches 11 shown in FIG. 4 and a plurality of diode trenches 21 shown in FIG. 10 as a plurality of trenches. Inside the active trenches 11, the gate trench electrodes 11a are provided as the first trench electrodes. Inside the diode trenches 21, the diode trench electrodes 21a are provided as the second trench electrodes. The gate trench electrodes 11a and the diode trench electrodes 21a may collectively be referred to as a plurality of trench electrodes. The interlayer insulation film 4 covers two or more first trench electrodes, i.e., two or more gate trench electrodes 11a, among the trench electrodes.

The openings 4a of the interlayer insulation film 4 in the diode area 20 are provided between the gate trench electrodes 11a covered with the interlayer insulation film 4. For example, in the case where both edges of one diode area 20 is sandwiched between two IGBT areas 10 as shown in FIG. 1 or 2, the openings 4a are formed between the gate trench electrodes 11a in one of the IGBT areas 10 and the gate trench electrodes 11a in the other IGBT area 10. The upper surfaces of the p⁺-type contact layer 24 and the diode trenches 21 shown in FIG. 10 correspond to the bottoms of the openings 4a.

In other words, the diode trench electrodes 21a are provided inside the openings 4a of the interlayer insulation film 4. The diode trench electrodes 21a in the diode area 20 are not covered with the interlayer insulation film 4 and is electrically connected to the emitter electrode 6. The number of diode trench electrodes 21a may be one or more.

Like the dummy trench electrodes 12a shown in FIG. 6, the upper surface of each diode trench electrode 21a includes a first recessed portion 51. The first recessed portion 51 is provided in the central portion of the upper end in the widthwise direction of the diode trench electrode 21a. The first recessed portion 51 has a bottom located at a lower level than the upper surface of the semiconductor substrate. The diode trench electrode 21a has an upper end located at a lower level than the upper surface of the semiconductor substrate. The first recessed portion 51 forms the bottom of an opening 4a.

Like the upper surfaces of the dummy-trench insulation films 12b shown in FIGS. 6 and 7, the diode trench insulation films 21b each have an upper surface that includes a fifth recessed portion 55. The fifth recessed portions 55 are located at a lower level than the upper surface of the semiconductor substrate. The fifth recessed portions 55 form the bottoms of the openings 4a.

Like the area for forming the dummy trenches 12 shown in FIG. 6, the first emitter electrode 6b is provided on the semiconductor substrate so as to fill the openings 4a of the interlayer insulation film 4 via the barrier metal 5. The barrier metal 5 is formed on the first recessed portions 51 and the fifth recessed portions 55. In the case where the barrier metal 5 is not provided, the first emitter electrode 6b is formed in the first recessed portions 51 and the fifth recessed portions 55.

The first emitter electrode 6b has an upper surface that includes third recessed portions 53 located immediately above the openings 4a. The third recessed portions 53 may further include recessed portions (not shown) immediately above the first recessed portions 51 located inside the openings 4a. The third recessed portions 53 are formed so as to follow the shapes of the first recessed portions 51 or the openings 4a.

The second emitter electrode 6c is provided on the first emitter electrode 6b. The second emitter electrode 6c may have an upper surface that includes fourth recessed portions 54 immediately above the third recessed portions 53. The fourth recessed portions 54 are formed so as to follow the shapes of the third recessed portions 53.

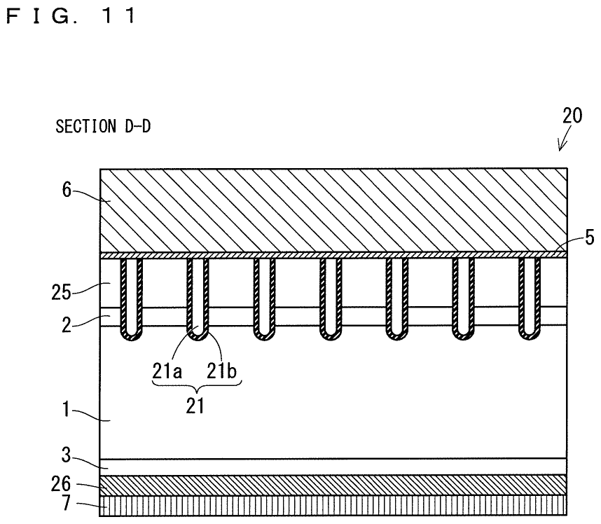

FIG. 11 is a sectional view showing the configuration of one diode area 20 of the semiconductor device 100 or 101. FIG. 11 shows a section taken along a broken line D-D shown in FIG. 9.

The section shown in FIG. 11 differs from the section shown in FIG. 10 in that the p⁺-type contact layer 24 is not provided on the first main surface side of the semiconductor substrate. As shown in FIG. 9, the p⁺-type contact layer 24 is selectively formed as a surface layer on the first main surface side of the semiconductor substrate. Thus, the p⁺-type contact layer 24 does not exist in the section shown in FIG. 11. In areas of the diode area 20 in which the p⁺-type contact layer 24 is not provided, the first main surface of the semiconductor substrate corresponds to the surface (upper surface) of the p-type anode layer 25. In the section shown in FIG. 11, one diode cell includes the p-type anode layer 25, the n-type carrier stored layer 2, the n⁻-type drift layer 1, the n-type buffer layer 3, the n⁺-type cathode layer 26, the barrier metal 5, the emitter electrode 6, and the collector electrode 7.

Although not shown, even in the structure shown in FIG. 11, the semiconductor devices 100 and 101 include the first recessed portions 51, the third recessed portions 53, the fourth recessed portions 54, and the fifth recessed portions 55.

The configuration in the first recessed portions 51, the third recessed portions 53, the fourth recessed portions 54, and the fifth recessed portions 55 are formed in the diode area 20 is not limited to the aforementioned example. The first recessed portions 51, the third recessed portions 53, the fourth recessed portions 54, and the fifth recessed portions 55 may be formed even in such a semiconductor device that some of the diode trenches (not shown), among the diode trenches 21 are covered with the interlayer insulation film 4. In that case, among the diode trenches 21, the first diode trenches covered with the interlayer insulation film 4 serve as first diode trench electrodes, and the second diode trench electrodes that are not covered with the interlayer insulation film 4 serve as second trench electrodes. The first diode trench electrodes are electrically connected to the emitter electrode 6 on any areas of the first diode trench electrodes. Each opening 4a in the diode area 20 is provided between two first diode trench electrodes covered with the interlayer insulation film 4. At least one second diode trench electrode is provided on the inner side of the opening 4a of the interlayer insulation film 4. Even in this configuration, the first recessed portions 51, the third recessed portions 53, the fourth recessed portions 54, and the fifth recessed portions 55 are formed in the diode area 20.

### (4) Structure of Boundary Portion between IGBT Area 10 and Diode Area 20

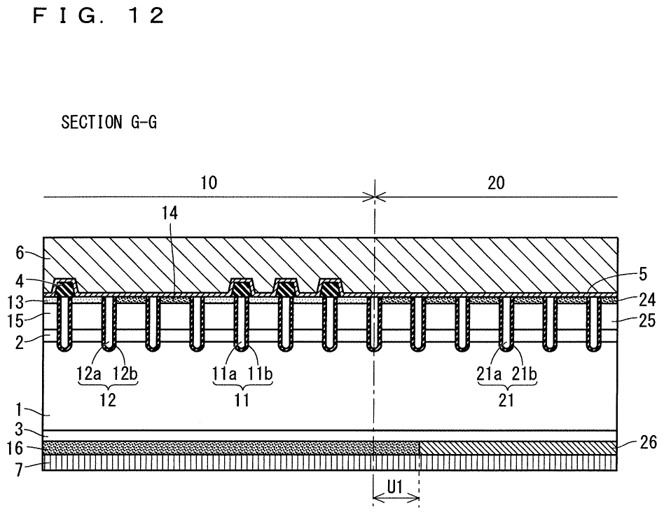

FIG. 12 is a sectional view showing a configuration of a boundary portion between one IGBT area 10 and one diode area 20. FIG. 12 shows a section taken along a broken line G-G shown in FIG. 1 or 2.

The p-type collector layer 16 provided on the second main surface of the IGBT area 10 extends off the diode area 20 by a distance U1 from the boundary between the IGBT area 10 and the diode area 20. In this case, the distance between the n⁺-type cathode layer 26 and the active trench 11 increases as compared with the structure in which the p-type collector layer 16 does not extend off the diode area 20. This structure reduces the current flowing from the channel formed adjacent to the active trenches 11 to the n⁺-type cathode layer 26, even if a gate driving voltage is applied to the gate trench electrodes 11a during freewheeling diode operation. The distance U1 may, for example, be 100 μm. It is, however, noted that the distance U1 may be 0 μm or shorter than 100 μm depending on the application of the semiconductor device 100 or 101.

### (5) Structure of Termination Area 30

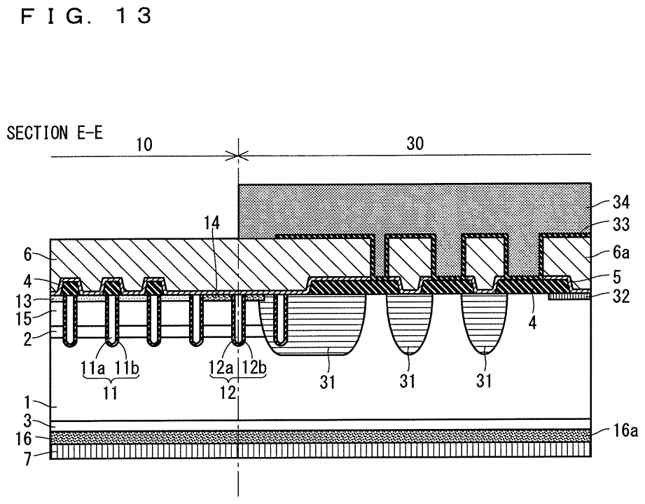

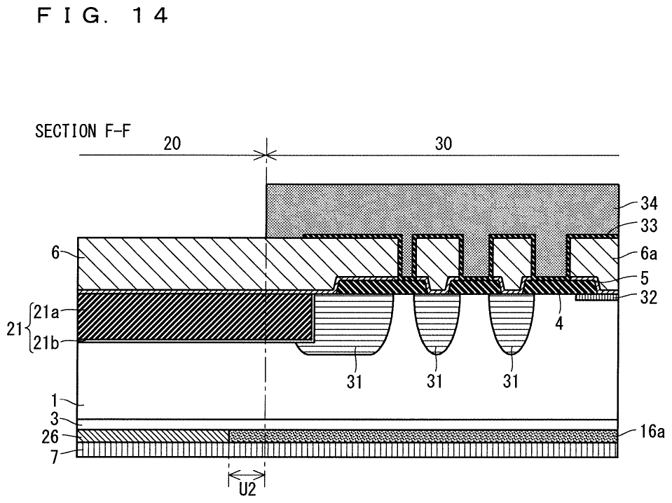

FIG. 13 is a sectional view showing a configuration of a boundary portion between one IGBT area 10 and the termination area 30. FIG. 13 shows a section taken along a broken line E-E shown in FIG. 1 or 2. FIG. 14 is a sectional view showing a configuration of a boundary portion between one diode area 20 and the termination area 30. FIG. 14 shows a section taken along a broken line F-F shown in FIG. 1.

In the termination area 30, the semiconductor devices 100 and 101 include p-type terminal well layers 31, an n⁺-type channel stopper layer 32, the n⁻-type drift layer 1, the n-type buffer layer 3, the p-type terminal collector layer 16a, the interlayer insulation film 4, the barrier metal 5, the emitter electrode 6, terminal electrodes 6a, a semi-insulation film 33, a terminal protective film 34, and the collector electrode 7.

In the aforementioned structure, the p-type terminal well layer 31, the n⁺-type channel stopper layer 32, the n⁻-type drift layer 1, the n-type buffer layer 3, and the p-type terminal collector layer 16a are provided between the first and second main surfaces of the semiconductor substrate.

The first main surface of the semiconductor substrate in the termination area 30 corresponds to the surfaces (upper surfaces) of the n⁻-type drift layer 1, the p-type terminal well layer 31, and the n⁺-type channel stopper layer 32. This first main surface in the termination area 30 continues from the first main surface in the IGBT area 10 or the diode area 20 and is in the same plane as the first main surface in the IGBT area 10 or the diode area 20. The second main surface of the semiconductor substrate in the termination area 30 corresponds to the surface (lower surface) of the p-type terminal collector layer 16a. The second main surface in the termination area 30 continues from the second main surface in the IGBT area 10 or the diode area 20 and is in the same plane.

Like the n⁻-type drift layer 1 in the IGBT area 10 and the diode area 20, the n⁻-type drift layer 1 is provided between the first and second main surfaces of the semiconductor substrate. Part of the n⁻-type drift layer 1 in the termination area 30 is exposed to the first main surface as a surface layer of the semiconductor substrate. The n⁻-type drift layer 1 in the termination area 30 is continuously and integrally formed with the n⁻-type drift layer 1 in the IGBT area 10 and the diode area 20.

The p-type terminal well layers 31 are provided on the first main surface side of the semiconductor substrate with respect to the n-type drift layer 1. The p-type terminal well layer 31 surrounds the cell area in plan view. In the present embodiment, three p-type terminal well layers 31 form three rings and surround the cell area in plan view. The three p-type terminal well layers 31 form an FLR. The number of p-type terminal well layers 31 is, however, not limited to three. The number of p-type terminal well layers 31 may be selected as appropriate depending on the withstand voltage design of the semiconductor device 100 or 101. The p-type terminal well layers 31 are semiconductor layers that may contain, for example, boron or aluminum as a p-type impurity. The concentration of the p-type impurity in the p-type terminal well layers 31 is higher than or equal to 1.0E+14/cm³ and lower than or equal to 1.0E+19/cm³.

The n⁺-type channel stopper layer 32 is provided on the first main surface side of the semiconductor substrate with respect to the n⁻-type drift layer 1. The n⁺-type channel stopper layer 32 is provided outside the p-type terminal well layers 31 in plan view. The n⁺-type channel stopper layer 32 is provided so as to surround the p-type terminal well layers 31.

The n-type buffer layer 3 is provided on the second main surface side of the semiconductor substrate with respect to the n⁻-type drift layer 1. The n-type buffer layer 3 provided in the termination area 30 is similar in configuration to the n-type buffer layer 3 provided in the IGBT area 10 or the diode area 20. The n-type buffer layer 3 provided in the termination area 30 is continuously and integrally formed with the n-type buffer layer 3 provided in the IGBT area 10 or the diode area 20.

The p-type terminal collector layer 16a is provided on the second main surface side of the semiconductor substrate with respect to the n-type buffer layer 3. The p-type terminal collector layer 16a is continuously and integrally formed with the p-type collector layer 16 provided in the IGBT area 10. The p-type terminal collector layer 16a in the termination area 30 and the p-type collector layer 16 in the IGBT area 10 may be collectively defined as one p-type collector layer.

As shown in FIG. 14, the p-type terminal collector layer 16a extends off the diode area 20 by a distance U2 from the boundary between the diode area 20 and the termination area 30. Accordingly, the distance between the n⁺-type cathode layer 26 and the p-type terminal well layers 31 increases as compared with that in the structure in which the p-type terminal collector layer 16 does not extend off the diode area 20. This structure prevents the p-type terminal well layers 31 from operating as the anode of the freewheeling diode. The distance U2 may, for example, be 100 μm.

The interlayer insulation film 4 is provided on the first main surface of the semiconductor substrate. The interlayer insulation film 4 has contact holes. The contact holes are provided on the p-type terminal well layers 31 and on the n⁺-type channel stopper layer 32. The surfaces of the p-type terminal well layers 31 or the n⁺-type channel stopper layer 32 are exposed through the contact holes.

The barrier metal 5 is provided on the p-type terminal well layers 31 and on the n⁺-type channel stopper layer 32.

The emitter electrode 6 is electrically connected to a p-type terminal well layer 31 that is located close to the IGBT area 10 or the diode area 20 via the barrier metal 5. The emitter electrode 6 in the termination area 30 is continuously and integrally formed with the emitter electrode 6 in the IGBT area 10 or the diode area 20.

The terminal electrodes 6a are separated from the emitter electrode 6 and provided outward of the emitter electrode 6. The terminal electrodes 6a are electrically connected to the p-type terminal well layers 31 and the n⁺-type channel stopper layer 32 via the barrier metal 5 in the contact holes.

The semi-insulation film 33 provides electrical connection between the emitter electrode 6 and the terminal electrodes 6a. The semi-insulation film 33 may, for example, be a semi-insulating silicon nitride (sin SiN) film.

The terminal protective film 34 covers the emitter electrode 6, the terminal electrodes 6a, and the semi-insulation film 33. The terminal protective film 34 may be formed of, for example, polyimide.

The collector electrode 7 is provided on the p-type terminal collector layer 16a, i.e., the second main surface of the semiconductor substrate. The collector electrode 7 in the termination area 30 is continuously and integrally formed with the collector electrode 7 in the IGBT area 10 and the diode area 20.

### (6) Method of Manufacturing Semiconductor Device 100 or 101

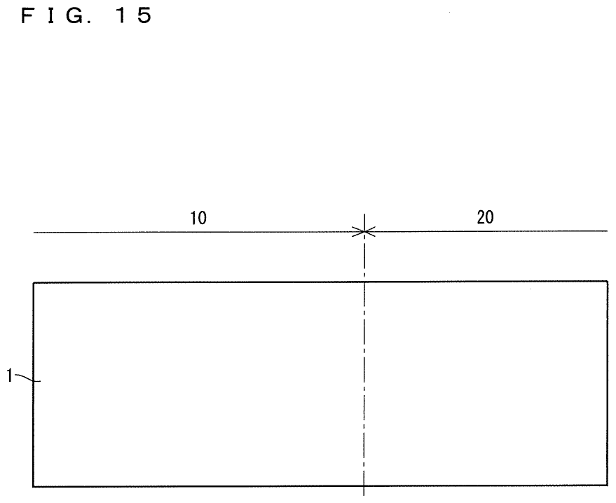

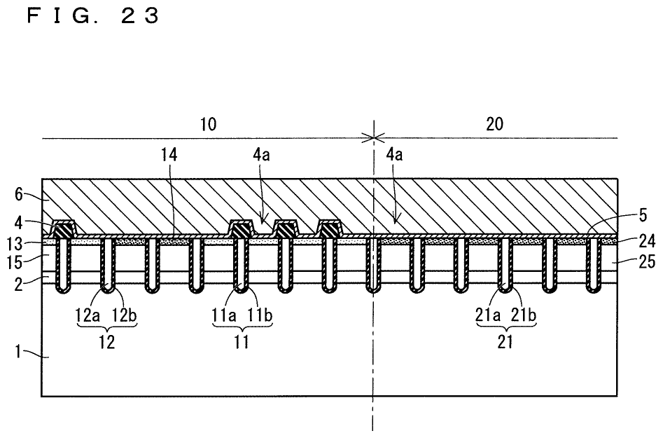

FIGS. 15 to 26 are diagrams showing a method of manufacturing the semiconductor device 100 or 101. FIGS. 15 to 22 show the steps of forming the structure on the first main surface side of the semiconductor device 100 or 101. FIGS. 23 to 26 show the steps of forming the structure on the second main surface side of the semiconductor device 100 or 101. Each drawing shows a section of the boundary portion between the IGBT area 10 and the diode area 20, i.e., a section taken along a broken line G-G shown in FIG. 1 or 2.

FIG. 15 is a diagram showing the step of preparing the semiconductor substrate. In the present embodiment, an n-type wafer that contains an n-type impurity is prepared as the semiconductor substrate. The semiconductor substrate may be a so-called floating zone (FZ) wafer produced by the FZ method, or may be a so-called magnetic field applied Czochralki (MCZ) wafer produced by the MCZ method. As another alternative, the semiconductor substrate may also be a wafer produced by sublimation or chemical vapor deposition (CVD). In this step, the semiconductor substrate as a whole corresponds to the n⁻-type drift layer 1. The concentration of the n-type impurity may be selected as appropriate according to the withstand voltage specification of the semiconductor device 100 or 101. For example, in the case where the withstand voltage specification of the semiconductor device 100 or 101 is 1200V, the concentration of the n-type impurity is adjusted such that the n-type drift layer 1 has resistivity of appropriately 40 to 120 Ω·cm. Although the step of preparing an n-type wafer in which the semiconductor substrate as a whole serves as the n⁻-type drift layer 1 is shown in FIG. 15, the step of preparing the semiconductor substrate is not limited thereto. For example, the semiconductor substrate including the n⁻-type drift layer 1 may be prepared by the step of implanting n-type impurity ions from the first or second main surface of the semiconductor substrate and the step of diffusing the n-type impurity by heat treatment.

The semiconductor substrate has defined therein the IGBT areas 10 in which IGBT cells are to be arranged and the diode areas 20 in which diode cells are to be arranged. Although not shown in FIG. 15, the termination area 30 in which the withstand voltage holding structure is to be formed is defined around the IGBT areas 10 and the diode areas 20. The following description is primarily given of the method of manufacturing each structure in the IGBT areas 10 and the diode areas 20.

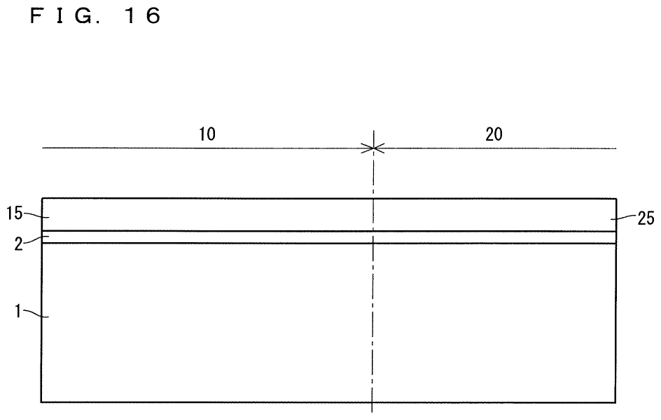

FIG. 16 is a diagram showing the step of forming the n-type carrier stored layer 2, the p-type base layer 15, and the p-type anode layer 25. Here, n-type impurity ions for forming the n-type carrier stored layer 2 are implanted into the surface layer of the n-type drift layer 1 from the first main surface side of the semiconductor substrate. The n-type impurity may, for example, phosphorus. Then, p-type impurity ions for forming the p-type base layer 15 and the p-type anode layer 25 are implanted into the first main surface of the semiconductor substrate. The p-type impurity may, for example, be boron. After the ion implantation, heat treatment is performed. Through the heat treatment, the n-type impurity and the p-type impurity are diffused to form the n-type carrier stored layer 2, the p-type base layer 15, and the p-type anode layer 25.

At the time of the aforementioned ion implantation, a mask having openings in predetermined areas is formed on the first main surface of the semiconductor substrate. The n-type impurity and the p-type impurity are implanted into the areas corresponding to the openings of the mask. The mask is formed by the step of applying a resist to the first main surface of the semiconductor substrate and the step of forming openings in predetermined areas of the resist by photolithography. Hereinafter, the processing for forming a mask having openings in predetermined areas is referred to as masking. The n-type impurity and the p-type impurity are implanted into the predetermined areas by masking. As a result, the n-type carrier stored layer 2, the p-type base layer 15, and the p-type anode layer 25 are selectively formed in the first main surface of the semiconductor substrate.

The p-type base layer 15 and the p-type anode layer 25 may be formed by implanting p-type impurity ions at the same time. In this case, the p-type base layer 15 and the p-type anode layer 25 are configured to have the same depth and the same p-type impurity concentration. Alternatively, the p-type base layer 15 and the p-type anode layer 25 may be formed by implanting p-type impurity ions separately through masking. In this case, the p-type base layer 15 and the p-type anode layer 25 are configured to have different depths and different p-type impurity concentrations. For example, p-type impurity ions for forming the p-type base layer 15 may be implanted through the openings provided in the IGBT areas 10. Also, p-type impurity ions for forming the p-type anode layer 25 may be implanted through the openings provided in the diode area 20.

Although not shown, the p-type terminal well layers 31 in the termination area 30 and the p-type anode layer 25 in the diode area 20 may also be formed by implanting p-type impurity ions at the same time. In this case, the p-type terminal well layers 31 and the p-type anode layer 25 have the same depth and the same p-type impurity concentration. Even in the case where the p-type terminal well layer 31 and the p-type anode layer 25 are configured to have different p-type impurity concentrations, p-type impurity ions may be implanted at the same time. In this case, however, a meshed mask is provided in at least one of the area in which the p-type terminal well layers 31 are to be formed and the area in which the p-type anode layer 25 is to be formed. The amount of the p-type impurity to be implanted is controlled in accordance with the aperture ratio of the mesh.

The p-type terminal well layers 31 and the p-type anode layer 25 may be formed by implanting p-type impurity ions separately through masking. In this case, the p-type terminal well layers 31 and the p-type anode layer 25 have different depths and different p-type impurity concentrations.

The p-type terminal well layers 31, the p-type base layer 15, and the p-type anode layer 25 may also be formed by implanting p-type impurity ions at the same time. The p-type terminal well layers 31 may also be formed by implanting p-type impurity ions before machining of the IGBT area 10 and the diode area 20.

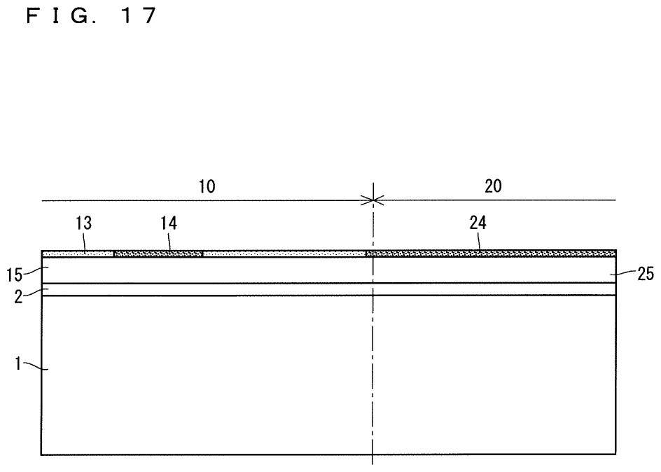

FIG. 17 is a diagram showing the step of forming the n⁺-type source layer 13, the p⁺-type contact layer 14, and the p⁺-type contact layer 24. Here, n-type impurity ions are implanted into the surface layer of the p-type base layer 15 from the first main surface side of the semiconductor substrate. At this time, the n-type impurity is implanted into the IGBT area 10 by masking. Accordingly, the n⁺-type source layer 13 is selectively formed in the surface layer of the p-type base layer 15 in the IGBT area 10. The n-type impurity may, for example, be arsenic or phosphorus.

Then, p-type impurity ions are implanted from the first main surface side of the semiconductor substrate. At this time, the openings of the mask are arranged such that the p-type impurity is implanted into predetermined areas of the IGBT area 10 and predetermined areas of the diode area 20. Through this masking, the p⁺-type contact layer 14 and the p⁺-type contact layer 24 are selectively formed in the surface layer of the p-type base layer 15 in the IGBT area 10 and the diode area 20. The p-type impurity may, for example, be boron or aluminum.

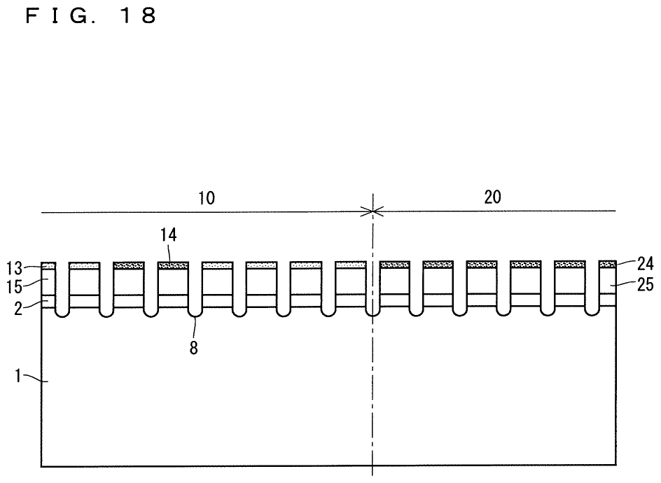

FIG. 18 is a diagram showing the step of forming trench structures 8. The trench structures 8 are formed by the step of depositing a material for hard mask on the first main surface of the semiconductor substrate, the step of forming a hard mask having openings in portions corresponding to the trench structures 8 by photolithography, and the step of etching the semiconductor substrate through the hard mask. The hard mask may, for example, be a thin film such as SiO₂.

The trench structures 8 in the IGBT area 10 extend from the first main surface of the semiconductor substrate to the n-type drift layer 1 through the p-type base layer 15 and the n-type carrier stored layer 2. Some of the trench structures 8 formed in the IGBT area 10 also penetrate the n⁺-type source layer 13, and another some of the trench structures 8 also penetrate the p⁺-type contact layer 14. The trench structures 8 in the diode area 20 extend from the first main surface of the semiconductor substrate to the n⁻-type drift layer 1 through the p-type anode layer 25 and the n-type carrier stored layer 2. In the area in which the p⁺-type contact layer 24 is provided as the surface layer of the semiconductor substrate, the trench structures 8 also penetrate the p⁺-type contact layer 24.

In FIG. 18, the pitch of the trench structures 8 in the IGBT area 10 is the same as the pitch of the trench structures 8 in the diode area 20. However, the pitch of the trench structures 8 in the IGBT area 10 may be different from the pitch of the trench structures 8 in the diode area 20. The pitch of the trench structures 8 may be changed as appropriate depending on the pattern of the mask used in masking.

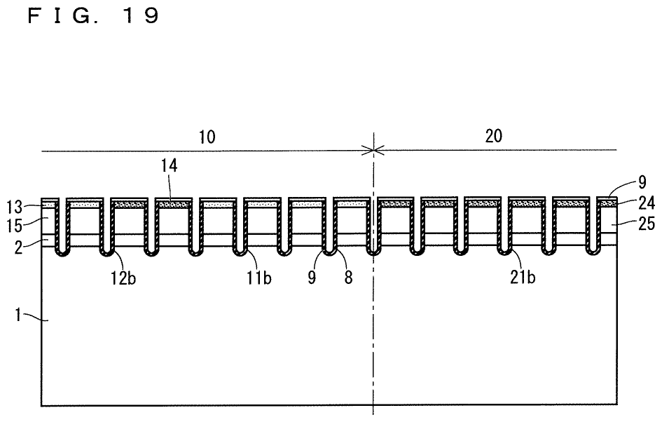

FIG. 19 is a diagram showing the step of forming an oxide film 9. The semiconductor substrate is heated in an oxygen-containing atmosphere. The oxide film 9 is formed on the inner walls of the trench structures 8 and the first main surface of the semiconductor substrate. In the IGBT area 10, the oxide film 9 formed on the inner walls of the trench structures 8 penetrating the n⁺-type source layer 13 corresponds to the gate-trench insulation films 11b. Similarly, in the IGBT area 10, the oxide film 9 formed on the inner walls of the trench structures 8 penetrating the p⁺-type contact layer 14 corresponds to the dummy-trench insulation films 12b. In the diode area 20, the oxide film 9 formed on the trench structures 8 corresponds to the diode trench insulation films 21b. Note that the oxide film 9 formed on the first main surface of the semiconductor substrate is removed in a subsequent step.

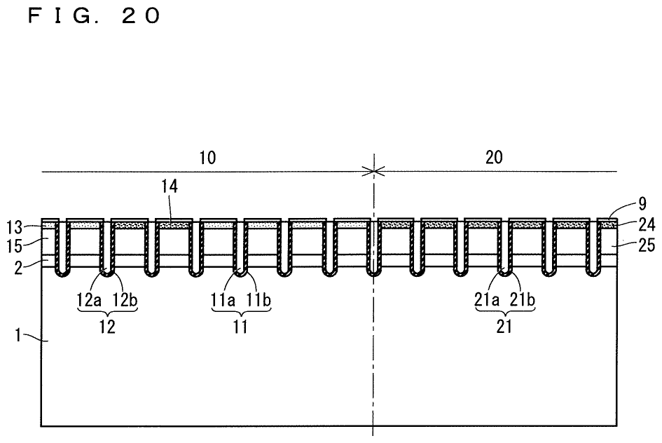

FIG. 20 is a diagram showing the step of forming the gate trench electrodes 11a, the dummy trench electrodes 12a, and the diode trench electrodes 21a. Here, polysilicon doped with an n-or p-type impurity is deposited inside the trench structures 8 by chemical vapor deposition (CVD) or any other technique. As a result, the gate trench electrodes 11a are formed inside the trench structures 8 via the gate-trench insulation films 11b. The dummy trench electrodes 12a are formed inside the trench structures 8 via the dummy-trench insulation films 12b. The diode trench electrodes 21a are formed inside the trench structures 8 via the diode trench insulation films 21b.

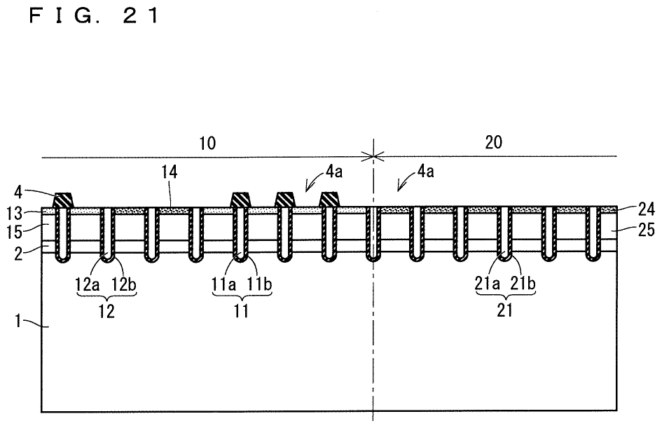

FIG. 21 is a diagram showing the step of forming the interlayer insulation film 4. The interlayer insulation film 4 is formed on the gate trench electrodes 11a among the plurality of trench electrodes. In this step, firstly the interlayer insulation film 4 is formed on the upper surface of the semiconductor substrate. The interlayer insulation film 4 may contain, for example, SiO₂ as an oxide film. For example, the interlayer insulation film 4 may have a single-layer structure including the oxide film. The oxide film in the single-layer structure may be formed of, for example, tetraethoxysilane (TEOS). The interlayer insulation film 4 may have a laminated structure including a plurality of oxide films. In the case where the interlayer insulation film 4 has a laminated structure, the oxide films may include two or more types of oxide films having different dopant concentrations. Among the two or more types of oxide films, the oxide film in the first layer may be formed of TEOS containing boron and phosphorus (BPTEOS), and the oxide film in the second layer may be formed of TEOS.

Thereafter, the interlayer insulation film 4 is subjected to masking so that the interlayer insulation film 4 and the oxide film 9 in predetermined positions are etched. Specifically, the interlayer insulation film 4 and the oxide films 9 on the dummy trench electrodes 12a and the diode trench electrodes 21a are removed. Accordingly, the openings 4a are formed in the interlayer insulation film 4. The openings 4a are located between the gate trench electrodes 11a covered with the interlayer insulation film 4. The n⁺-type source layer 13, the p⁺-type contact layer 14, the p⁺-type contact layer 24, the upper surfaces of the dummy trenches 12, and the upper surfaces of the diode trenches 21 are exposed through the openings 4a. The first recessed portions 51 in the upper surfaces of the diode trench electrodes 21a and the dummy trench electrodes 12a form part of the bottoms of the openings 4a.

At the time of forming the openings 4a, the upper parts of the dummy-trench insulation films 12b that are in contact with the dummy trench electrodes 12a and the upper parts of the diode trench insulation films 21b that are in contact with the diode trench electrodes 21a are also removed. Accordingly, the fifth recessed portions 55 are formed in the upper surfaces of the dummy-trench insulation films 12b and the upper surfaces of the diode trench insulation films 21b as shown in FIG. 6.

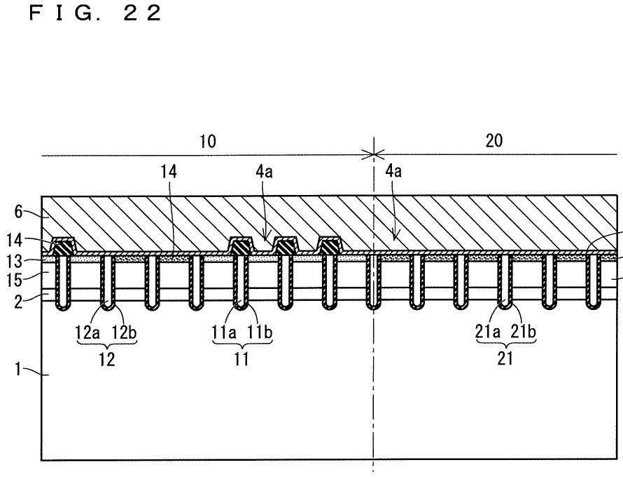

FIG. 22 is a diagram showing the step of forming the barrier metal 5 and the emitter electrode 6. The barrier metal 5 is formed on the first main surface of the semiconductor substrate and on the interlayer insulation film 4. For example, the barrier metal 5 may preferably be titanium-containing metal such as Ti, TiN, or TiSi. The barrier metal 5 may be produced by CVD or physical vapor deposition (PVD).

The emitter electrode 6 is formed on the barrier metal 5. As shown in FIGS. 5 and 6, the emitter electrode 6 includes the first emitter electrode 6b and the second emitter electrode 6c. The first emitter electrode 6b is formed by the PVD method such as sputtering or evaporation. For example, the first emitter electrode 6b may contain an aluminum-silicon alloy (Al—Si-based alloy). The second emitter electrode 6c is formed on the first emitter electrode 6b by electroless plating or electroplating. For example, the second emitter electrode 6c may contain nickel or a nickel alloy. The second emitter electrode 6c may have, for example, a laminated structure that includes two or more types of metal layers. This laminated structure may be configured by an Ni film, a Pd film, and an Au film and formed by plating.

Plating allows easy formation of a thick metal film. Since the thick-film emitter electrode 6 increases thermal capacity, the heat resistance of the emitter electrode 6 improves. In the case where a nickel alloy is further formed by plating on the aluminum-silicon alloy, the plating may be conducted after completion of machining on the second main surface side of the semiconductor substrate.

FIG. 23 is a diagram showing the step of reducing the thickness of the semiconductor substrate. The second main surface of the semiconductor substrate is ground to a predetermined thickness depending on the design of the semiconductor device 100 or 101. The thickness of the semiconductor substrate after grinding may, for example, be greater than or equal to 80 μm and less than or equal to 200 μm.

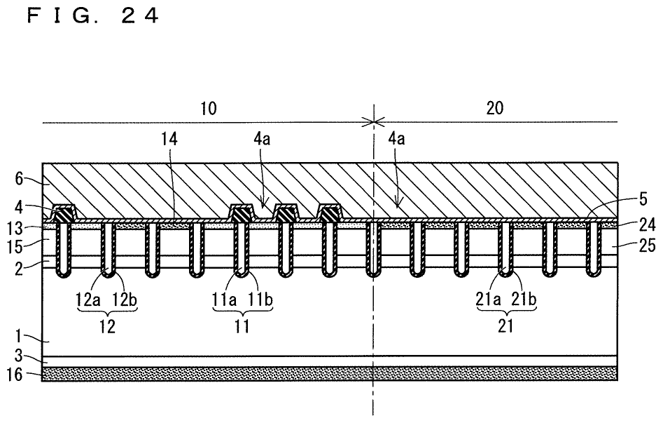

FIG. 24 is a diagram showing the step of forming the n-type buffer layer 3 and the p-type collector layer 16. Here, n-type impurity ions for forming the n-type buffer layer 3 are implanted into the surface layer of the n⁻-type drift layer 1 from the second main surface side of the semiconductor substrate. For example, phosphorus or proton may be implanted as an n-type impurity. Alternatively, both of phosphorus and proton may be implanted.

Proton is implanted into a deep position from the second main surface of the semiconductor substrate with relatively low acceleration energy. The implantation depth of proton can be relatively easily controlled by changing the acceleration energy. Thus, multiple proton ion implantations with different acceleration energies result in the formation of the n-type buffer layer 3 that is wider in the thickness direction of the semiconductor substrate than the n-type buffer layer 3 that contains phosphorus.

As compared with proton, phosphorus has a high activation rate as the n-type impurity. Even if the semiconductor substrate is reduced in thickness, the n-type buffer layer 3 that contains phosphorus can more reliably reduce the occurrence of punch-through resulting from the expansion of the depletion layer. In order to further reduce the thickness of the semiconductor substrate, it is preferable to form the n-type buffer layer 3 that contains both proton and phosphorus. In that case, proton is implanted into a deeper position than phosphorus from the second main surface of the semiconductor substrate.

Then, p-type impurity ions for forming the p-type collector layer 16 are implanted from the second main surface side of the semiconductor substrate. For example, boron ions may be implanted as the p-type impurity. After the ion implantation, laser is applied to the second main surface of the semiconductor substrate. This laser annealing activates the implanted boron and produces the p-type collector layer 16.

At the time of this laser annealing, phosphorus serving as the n-type impurity, which is implanted into a relatively shallow position from the second main surface of the semiconductor substrate, is also activated simultaneously. Proton is activated at a relatively low annealing temperature of approximately 350° C. to 500° C. Thus, it is preferable that, after the proton implantation, the semiconductor substrate is not heated to a temperature higher than 350° C. to 500° C. in steps other than the activation of proton. The laser annealing heats the semiconductor substrate in the vicinity of only the second main surface to a high temperature. Thus, the laser annealing is effective in activating the n- or p-type impurity after the proton implantation.

The n-type buffer layer 3 may be formed in the IGBT area 10, the diode area 20, and the termination area 30, or may be formed in only the IGBT area 10 or the diode area 20. The p-type collector layer 16 is also formed in the termination area 30. Here, the p-type collector layer 16 in the termination area 30 corresponds to the p-type terminal collector layer 16a.

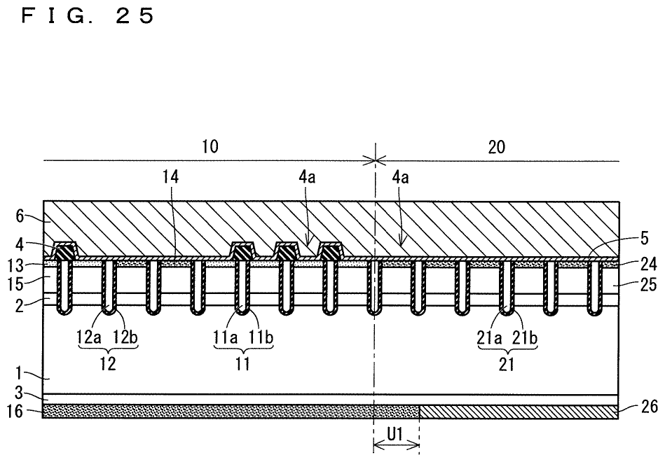

FIG. 25 is a diagram showing the step of forming the n⁺-type cathode layer 26. Here, n-type impurity ions for forming the n⁺-type cathode layer 26 are implanted into the second main surface of the semiconductor substrate in the diode area 20. As the n-type impurity, phosphorus is implanted. At this time, the n-type impurity is selectively implanted by masking so that the boundary between the p-type collector layer 16 and the n⁺-type cathode layer 26 enters toward the diode area 20 by the distance U1 from the boundary between the IGBT area 10 and the diode area 20.

The amount of n-type impurities to be implanted in order to form the n⁺-type cathode layer 26 is greater than the amount of p-type impurities contained in the p-type collector layer 16. The n-type impurities in the n⁺-type cathode layer 26 are implanted into the area where the p-type collector layer 16 is formed. That is, the implantation of the n-type impurities need to modify the p-type semiconductor into an n-type semiconductor. Thus, n-type impurities are implanted so as to make the n-type impurity concentration higher than the p-type impurity concentration in all the areas where the n⁺-type cathode layer 26 is formed.

Although FIG. 25 shows an example in which the depth of the p-type collector layer 16 and the depth of the n⁺-type cathode layer 26 from the second main surface are the same, the relationship in depth between the p-type collector layer 16 and the n⁺-type cathode layer 26 is not limited to the above example. The depth of the n⁺-type cathode layer 26 may be greater than or equal to the depth of the p-type collector layer 16.

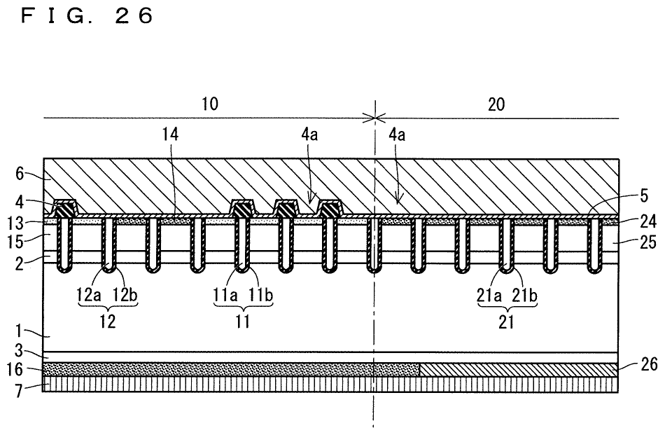

FIG. 26 is a diagram showing a step of forming the collector electrode 7. The collector electrode 7 is formed on the second main surface in the IGBT area 10, the diode area 20, and the termination area 30. The collector electrode 7 may be formed across the entire second main surface of the semiconductor substrate.

The collector electrode 7 may contain, for example, an aluminum-silicon alloy or titanium. The collector electrode 7 is formed by PVD such as sputtering or evaporation. The collector electrode 7 may be formed of a plurality of metal layers each containing an aluminum-silicon alloy, titanium, nickel, or gold. Alternatively, the collector electrode 7 may have a structure in which on a metal film formed of PVD, another metal film may be formed by electroless plating or electroplating.

In the embodiment, a plurality of semiconductor devices 100 or a plurality of semiconductor devices 101 are formed in a matrix on a single semiconductor substrate by the manufacturing steps described above. The semiconductor devices 100 or 101 are divided into individual semiconductor devices by laser dicing or blade dicing. Accordingly, the semiconductor devices 100 or 101 are completed.

In summary, the semiconductor devices 100 and 101 according to the embodiment includes a plurality of trenches, a plurality of trench electrodes, the interlayer insulation film 4, and the first emitter electrode 6b. The trenches are provided on the upper surface of the semiconductor substrate. The trenches correspond to any one of the active trenches 11, the dummy trenches 12, and the diode trenches 21. The plurality of trench electrodes are respectively provided in a plurality of trenches. The plurality of trench electrodes refer to one of the gate trench electrodes 11a, the dummy trench electrodes 12a, and the diode trench electrodes 21a. The interlayer insulation film 4 covers two or more trench electrodes among the plurality of trench electrodes. The two or more trench electrodes correspond to either the gate trench electrodes 11a or some of the diode trench electrodes 21a. The first emitter electrode 6b is provided on the interlayer insulation film 4. The interlayer insulation film 4 includes the opening 4a. The opening 4a is provided between two or more trench electrodes covered with the interlayer insulation film 4. The first emitter electrode 6b is provided on the semiconductor substrate so as to close the opening 4a. Each of the trench electrodes has an upper surface that includes a first recessed portion 51. The interlayer insulation film 4 has an upper surface that includes a second recessed portion 52 located immediately above the first recessed portion 51. The first emitter electrode 6b has an upper surface that includes a third recessed portion 53 located immediately above the opening 4a.

The semiconductor devices 100 and 101 further include the second emitter electrode 6c provided on the first emitter electrode 6b. The second emitter electrode 6c has an upper surface that includes the fourth recessed portion 54 located immediately above the third recessed portion 53. The third recessed portion 53 is further provided immediately above the second recessed portion 52 in the upper surface of the first emitter electrode 6b.

These semiconductor devices 100 and 101 increase the area of contact at each interface of the gate trench electrode 11a, the dummy trench electrode 12a, the diode trench electrode 21a, the interlayer insulation film 4, the first emitter electrode 6b, and the second emitter electrode 6c. Accordingly, adhesion properties improves. These uneven structure produces an anchor effect and accordingly improves stress tolerance. The depth of the fourth recessed portion 54 is shallower than the depth of the third recessed portion 53, the depths of the depth, second recessed portion 52, and the depth of the opening 4a, and the depth of the first recessed portion 51. Since the second emitter electrode 6c has a flat upper surface, assembly improves, for example, in wire bonding or solder bonding. In this way, the semiconductor devices 100 and 101 improve assembly and stress tolerance.

The bottom of the first recessed portion 51 is located below the upper surface of the semiconductor substrate. The upper end of each of the trench electrodes is located below the upper surface of the semiconductor substrate. This configuration increases the degree of dent of the second recessed portion 52. Accordingly, the area of contact and the anchor effect improve.

The interlayer insulation film 4 has a single-layer structure including an oxide film. In the case where the oxide film in the single-layer structure is formed of TEOS, the degree of unevenness increases. Accordingly, the area of contact and the anchor effect improves.

The interlayer insulation film 4 may have a laminated structure that contains two or more types of oxide films having different dopant concentrations. Among the two or more types of oxide films, one oxide film may be formed of TEOS (BPTEOS) including boron and phosphorus, and another oxide film is formed of TEOS. The degree of unevenness is controllable by changing the dopant concentration.

The thickness of the first emitter electrode 6b may be greater than the thickness of the second emitter electrode 6c. In that case, stress tolerance improves. On the contrary, the thickness of the second emitter electrode 6c may be greater than the thickness of the first emitter electrode 6b. In that case, wettability improves and high assembly is achieved.

The opening 4a may have a bottom having a greater width than the height of the interlayer insulation film 4 that forms the side wall of the opening 4a. This improves embeddedness of the first emitter electrode 6b or the barrier metal 5.

The first recessed portion 51 at the upper surface of the diode trench electrode 21a and the dummy trench electrode 12a forms part of the bottom of the opening 4a. This enlarges the area of contact between the first emitter electrode 6b or the barrier metal 5 and the semiconductor substrate.

Although the configuration described above is applied to both of the IGBT area 10 and the diode area 20 of the RC-IGBT, the configuration may be applied to only one of the diode area 20 or the IGBT area 10. Besides, the configuration described above is not only applied to the RC-IGBT. The configuration is also applicable to an IGBT as a simple substance or a semiconductor device including a diode as a simple substance, and even in such a case, the effects described above can be achieved.

The embodiment of the present disclosure may be modified or omitted as appropriate.

Hereinafter, various modes of the present disclosure are described as appendices in summary.

### Appendix 1

A semiconductor device comprising:
a plurality of trenches provided on an upper surface of a semiconductor substrate;
a plurality of trench electrodes provided respectively inside the plurality of trenches;
an insulation film that covers two or more trench electrodes among the plurality of trench electrodes; and
a first electrode provided on the insulation film,
wherein the insulation film has an opening provided between the two or more trench electrodes covered with the insulation film,
the first electrode is provided on the semiconductor substrate to fill the opening,
each of the plurality of trench electrodes has an upper surface that includes a first recessed portion,
the insulation film has an upper surface that includes a second recessed portion located immediately above the first recessed portion, and
the first electrode has an upper surface that includes a third recessed portion located immediately above the opening.

### Appendix 2

The semiconductor device according to Appendix 1, wherein
the third recessed portion is further provided immediately above the second recessed portion in the upper surface of the first electrode.

### Appendix 3

The semiconductor device according to Appendix 1 or 2, further comprising:
a second electrode provided on the first electrode,
wherein the second electrode has an upper surface that includes a fourth recessed portion located immediately above the third recessed portion.

### Appendix 4

The semiconductor device according to Appendix 3, wherein
the fourth recessed portion has a shallower depth than the third recessed portion.

### Appendix 5

The semiconductor device according to Appendix 3 or 4, wherein
the depth of the fourth recessed portion is shallower than a depth of the second recessed portion and a depth of the opening.

### Appendix 6

The semiconductor device according to any one of Appendices 3 to 5, wherein
the depth of the fourth recessed portion is shallower than a depth of the first recessed portion.

### Appendix 7

The semiconductor device according to any one of Appendices 1 to 6, wherein
the first recessed portion has a bottom located at a lower level than the upper surface of the semiconductor substrate.

### Appendix 8

The semiconductor device according to any one of Appendices 1 to 7, wherein
each of the plurality of trench electrodes has an upper end located at a lower level than the upper surface of the semiconductor substrate.

### Appendix 9

The semiconductor device according to any one of Appendices 1 to 8, wherein
the insulation film has a single-layer structure that includes an oxide film.

### Appendix 10

The semiconductor device according to any one of Appendices 1 to 9, wherein
the insulation film has a laminated structure that includes two or more types of oxide films having different dopant concentrations.

### Appendix 11

The semiconductor device according to Appendix 3, wherein
the first electrode has a greater thickness than the second electrode.

### Appendix 12

The semiconductor device according to Appendix 3, wherein
the second electrode has a greater thickness than the first electrode.

### Appendix 13

The semiconductor device according to any one of Appendices 1 to 12, wherein
the opening has a bottom having a width greater than a height of the insulation film that forms a side wall of the opening.

### Appendix 14

The semiconductor device according to Appendix 3, wherein
the second electrode has a laminated structure that includes two or more types of metal layers.

### Appendix 15

The semiconductor device according to any one of Appendices 1 to 14, wherein
the first electrode is in contact with the upper surface of the semiconductor substrate at a bottom of the opening.

### Appendix 16

The semiconductor device according to any one of Appendices 1 to 15, wherein
each of the two or more trench electrodes covered with the insulation film is a gate electrode of an insulated gate bipolar transistor (IGBT) formed on the semiconductor substrate.

### Appendix 17

The semiconductor device according to any one of Appendices 1 to 16, wherein
the plurality of trench electrodes include:
a plurality of first trench electrodes serving as the two or more trench electrodes and covered with the insulation film; and
at least one second trench electrode provided on an inner side of the opening of the insulation film,
each of the plurality of first trench electrodes is a gate electrode of an insulated gate bipolar transistor (IGBT) formed on the semiconductor substrate,
the at least one second trench electrode is not covered with the insulation film and is electrically connected to the first electrode, and
the first recessed portion in the upper surface of the at least one second trench electrode forms part of a bottom of the opening.

### Appendix 18

The semiconductor device according to Appendix 17, wherein
the at least one second trench electrode is formed inside each of the plurality of trenches via a trench insulation film provided along an inner wall of each of the plurality of trenches, and
the trench insulation film that is in contact with the at least one second trench electrode has an upper surface that includes a fifth recessed portion located below the upper surface of the semiconductor substrate.

### Appendix 19

A method of manufacturing a semiconductor device being a method of manufacturing the semiconductor device according to Appendix 3,
the method of manufacturing a semiconductor device, comprising:
forming the first electrode by sputtering; and
forming the second electrode by plating.

### Appendix 20

A method of manufacturing a semiconductor device being a method of manufacturing the semiconductor device according to Appendix 17,
the method of manufacturing a semiconductor device, comprising:
preparing the semiconductor substrate that includes the plurality of trenches and the plurality of trench electrodes that are formed respectively inside the plurality of trenches; and
forming the insulation film that covers the plurality of first trench electrodes among the plurality of trench electrodes,
the forming the insulation film includes:
forming the insulation film on the plurality of trench electrodes; and
removing the insulation film on the at least one second trench electrode among the plurality of trench electrodes to form the opening of the insulation film between the plurality of first trench electrodes covered with the insulation film, and
the first recessed portion in the upper surface of the at least one second trench electrode forms part of a bottom of the opening.

### Appendix 21

A method of manufacturing a semiconductor device being a method of manufacturing the semiconductor device according to Appendix 18,
the method of manufacturing a semiconductor device, comprising:
preparing the semiconductor substrate that includes the plurality of trenches and the plurality of trench electrodes that are formed respectively inside the plurality of trenches;
forming the insulation film that covers the plurality of first trench electrodes among the plurality of trench electrodes;
forming the insulation film on the plurality of trench electrodes; and
removing the insulation film on the at least one second trench electrode among the plurality of trench electrodes to form the opening of the insulation film between the plurality of first trench electrodes covered with the insulation film,
wherein the forming the opening includes forming the fifth recessed portion by removing an upper portion of the trench insulation film that is in contact with the at least one second trench electrode.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a plurality of trenches provided on an upper surface of a semiconductor substrate;
a plurality of trench electrodes provided respectively inside the plurality of trenches;
an insulation film that covers two or more trench electrodes among the plurality of trench electrodes; and
a first electrode provided on the insulation film,
wherein the insulation film has an opening provided between the two or more trench electrodes covered with the insulation film,
the first electrode is provided on the semiconductor substrate to fill the opening,
each of the plurality of trench electrodes has an upper surface that includes a first recessed portion,
the insulation film has an upper surface that includes a second recessed portion located immediately above the first recessed portion, and
the first electrode has an upper surface that includes a third recessed portion located immediately above the opening.

2. The semiconductor device according to claim 1, wherein
the third recessed portion is further provided immediately above the second recessed portion in the upper surface of the first electrode.

3. The semiconductor device according to claim 1, further comprising:
a second electrode provided on the first electrode,
wherein the second electrode has an upper surface that includes a fourth recessed portion located immediately above the third recessed portion.

4. The semiconductor device according to claim 3, wherein
the fourth recessed portion has a shallower depth than the third recessed portion.

5. The semiconductor device according to claim 4, wherein
the depth of the fourth recessed portion is shallower than a depth of the second recessed portion and a depth of the opening.

6. The semiconductor device according to claim 5, wherein
the depth of the fourth recessed portion is shallower than a depth of the first recessed portion.

7. The semiconductor device according to claim 1, wherein
the first recessed portion has a bottom located at a lower level than the upper surface of the semiconductor substrate.

8. The semiconductor device according to claim 1, wherein
each of the plurality of trench electrodes has an upper end located at a lower level than the upper surface of the semiconductor substrate.

9. The semiconductor device according to claim 1, wherein
the insulation film has a single-layer structure that includes an oxide film.

10. The semiconductor device according to claim 1, wherein
the insulation film has a laminated structure that includes two or more types of oxide films having different dopant concentrations.

11. The semiconductor device according to claim 3, wherein
the first electrode has a greater thickness than the second electrode.

12. The semiconductor device according to claim 3, wherein
the second electrode has a greater thickness than the first electrode.

13. The semiconductor device according to claim 1, wherein
the opening has a bottom having a width greater than a height of the insulation film that forms a side wall of the opening.

14. The semiconductor device according to claim 3, wherein
the second electrode has a laminated structure that includes two or more types of metal layers.

15. The semiconductor device according to claim 1, wherein
the first electrode is in contact with the upper surface of the semiconductor substrate at a bottom of the opening.

16. The semiconductor device according to claim 1, wherein
each of the two or more trench electrodes covered with the insulation film is a gate electrode of an insulated gate bipolar transistor (IGBT) formed on the semiconductor

17. The semiconductor device according to claim 1, wherein
the plurality of trench electrodes include:
a plurality of first trench electrodes serving as the two or more trench electrodes and covered with the insulation film; and
at least one second trench electrode provided on an inner side of the opening of the insulation film,
each of the plurality of first trench electrodes is a gate electrode of an insulated gate bipolar transistor (IGBT) formed on the semiconductor substrate,
the at least one second trench electrode is not covered with the insulation film and is electrically connected to the first electrode, and
the first recessed portion in the upper surface of the at least one second trench electrode forms part of a bottom of the opening.

18. The semiconductor device according to claim 17, wherein
the at least one second trench electrode is formed inside each of the plurality of trenches via a trench insulation film provided along an inner wall of each of the plurality of trenches, and
the trench insulation film that is in contact with the at least one second trench electrode has an upper surface that includes a fifth recessed portion located below the upper surface of the semiconductor substrate.

19. A method of manufacturing a semiconductor device being a method of manufacturing the semiconductor device according to claim 3,
the method of manufacturing a semiconductor device, comprising:
forming the first electrode by sputtering; and
forming the second electrode by plating.

20. A method of manufacturing a semiconductor device being a method of manufacturing the semiconductor device according to claim 17,
the method of manufacturing a semiconductor device, comprising:
preparing the semiconductor substrate that includes the plurality of trenches and the plurality of trench electrodes that are formed respectively inside the plurality of trenches; and
forming the insulation film that covers the plurality of first trench electrodes among the plurality of trench electrodes,
the forming the insulation film includes:
forming the insulation film on the plurality of trench electrodes; and
removing the insulation film on the at least one second trench electrode among the 15 plurality of trench electrodes to form the opening of the insulation film between the plurality of first trench electrodes covered with the insulation film, and
the first recessed portion in the upper surface of the at least one second trench electrode forms part of a bottom of the opening.

21. A method of manufacturing a semiconductor device being a method of manufacturing the semiconductor device according to claim 18,
the method of manufacturing a semiconductor device, comprising:
preparing the semiconductor substrate that includes the plurality of trenches and the plurality of trench electrodes that are formed respectively inside the plurality of trenches;
forming the insulation film that covers the plurality of first trench electrodes among the plurality of trench electrodes;
forming the insulation film on the plurality of trench electrodes; and
removing the insulation film on the at least one second trench electrode among the plurality of trench electrodes to form the opening of the insulation film between the plurality of first trench electrodes covered with the insulation film,
wherein the forming the opening includes forming the fifth recessed portion by removing an upper portion of the trench insulation film that is in contact with the at least one second trench electrode.
